(19) United States
(12) Patent Application Publication
(10) Pub. No.: US 2022/0264769 A1
(43) Pub. Date: Aug. 18, 2022

(54) POWER CONVERTER AND METHOD FOR MANUFACTURING POWER CONVERTER

(71) Applicant: Mitsubishi Electric Corporation, Chiyoda-ku, Tokyo (JP)

(72) Inventors: Yu KISHIWADA, Chiyoda-ku, Tokyo (JP); Koji NAKAJIMA, Chiyoda-ku, Tokyo (JP); Taro KIMURA, Chiyoda-ku, Tokyo (JP); Kenichi TAMURA, Chiyoda-ku, Tokyo (JP); Yoshikazu NOZUKI, Chiyoda-ku, Tokyo (JP); Masaya NONOMURA, Chiyoda-ku, Tokyo (JP); Kenta FUJII, Chiyoda-ku, Tokyo (JP)

(73) Assignee: Mitsubishi Electric Corporation, Chiyoda-ku, Tokyo (JP)

(21) Appl. No.: 17/629,813

(22) PCT Filed: Aug. 26, 2020
(86) PCT No.: PCT/JP2020/032200

§ 371 Date: Jan. 25, 2022

(30) Foreign Application Priority Data
Sep. 9, 2019 (JP) 2019-163616

(51) Int. Cl. H05K 7/20; H05K 1/02; H05K 1/18

(52) U.S. Cl. CPC H05K 7/20509; H05K 1/181; H05K 1/0209; H05K 7/20409

(57) ABSTRACT

A power converter includes a cooler, a housing, a cooling plate, an insulating heat dissipation member, and a circuit board. The housing includes a bottom, a sidewall, and an internal space. The bottom is connected to the cooler. The cooling plate is connected to the bottom so as to stand upright with respect to the bottom. The insulating heat dissipation member is disposed on the cooling plate. The circuit board is connected to the cooling plate with the insulating heat dissipation member interposed therebetween. The cooling plate, the insulating heat dissipation member, and the circuit board are accommodated in the internal space of the housing. The cooling plate is disposed with a gap from the sidewall.

### TECHNICAL FIELD

The present disclosure relates to a power converter and a method for manufacturing the power converter.

### BACKGROUND ART

Conventionally, there is a power converter including a printed circuit board, a housing that accommodates the printed circuit board, and a cooler that cools the housing. For example, in a power converter described in U.S. Pat. No. 4,231,626 (PTL 1), the cooler is disposed below the housing and integrally molded with the housing. The printed circuit board is connected to a board mounting member with a heat conductive sheet interposed therebetween. The board mounting member is connected to a sidewall of the housing.

### CITATION LIST

### Patent Literature

PTL 1: U.S. Pat. No. 4,231,626

### SUMMARY OF INVENTION

### Technical Problem

In the power converter described in PTL 1, heat generated from the printed circuit board (circuit board) is transferred to the cooler through the heat conductive sheet (insulating heat dissipation member), the board mounting member, and the sidewall of the housing.

As the printed circuit board (circuit board) is disposed farther from the cooler, a length of the sidewall through which the heat passes becomes longer, so that a heat dissipation path also becomes longer. When the heat radiation path becomes long, cooling performance is degraded, so that the cooling performance of the printed circuit board (circuit board) disposed far from the cooler is degraded.

The present disclosure has been made in view of the above problems, and an object of the present disclosure is to provide a power converter capable of improving cooling performance of the circuit board.

### Solution to Problem

A power converter includes a cooler, a housing, at least one cooling plate, at least one insulating heat dissipation member, and at least one circuit board. The housing includes a bottom, a sidewall, and an internal space. The bottom is connected to a cooler. The sidewall extends from the bottom on a side opposite to the cooler with respect to the bottom. The internal space is surrounded by the bottom and the sidewall. The at least one cooling plate is connected to the bottom so as to stand upright with respect to the bottom. The at least one insulating heat dissipation member is disposed on the at least one cooling plate. The at least one circuit board is connected to the at least one cooling plate with the at least one insulating heat dissipation member interposed therebetween. The at least one cooling plate, the at least one insulating heat dissipation member, and the at least one circuit board are housed in the internal space of the housing. The at least one cooling plate is disposed with a gap from the sidewall.

### Advantageous Effects of Invention

According to the power converter of the present disclosure, the at least one circuit board is connected to the at least one cooling plate with the at least one insulating heat dissipation member interposed therebetween. The at least one cooling plate is connected to the bottom. The bottom of the housing is connected to the cooler. Thus, heat generated from the at least one circuit board is transferred to the cooler through the at least one insulating heat dissipation member, the at least one cooling plate, and the bottom. Consequently, the cooling performance of the circuit board can be improved.

In addition, because the cooling plate is disposed with the gap from the sidewall of the housing, design is easier than the case where the cooling plate is in contact with the sidewall of the housing. Consequently, the power converter that is easy to design can be provided.

### BRIEF DESCRIPTION OF DRAWINGS

FIG. 1 is an exploded perspective view schematically illustrating a configuration of a power converter according to a first embodiment of the present disclosure, and a wiring board is separated from a housing and a cooling plate.

FIG. 2 is an exploded perspective view schematically illustrating the configuration of the power converter according to the first embodiment of the present disclosure, and the wiring board is not illustrated in FIG. 2.

FIG. 3 is a plan view from above schematically illustrating the configuration of the power converter according to the first embodiment of the present disclosure, and the wiring board is not illustrated in FIG. 3.

FIG. 4 is a sectional view taken along a line IV-IV of FIG. 3.

FIG. 5 is a sectional view taken along a line V-V of FIG. 3.

FIG. 6 is a perspective view schematically illustrating a configuration of a first cooling plate according to the first embodiment of the present disclosure.

FIG. 7 is a perspective view schematically illustrating a configuration of a second cooling plate according to the first embodiment of the present disclosure.

FIG. 8 is a perspective view schematically illustrating a configuration of a third cooling plate according to the first embodiment of the present disclosure.

FIG. 9 is a perspective view schematically illustrating a configuration of a fourth cooling plate according to the first embodiment of the present disclosure.

FIG. 10 is a perspective view schematically illustrating a configuration of a power converter according to the first embodiment of the present disclosure.

FIG. 11 is a pattern view schematically illustrating a configuration of a first front surface of a first circuit board according to the first embodiment of the present disclosure.

FIG. 12 is a pattern view schematically illustrating a configuration of a first back face of the first circuit board according to the first embodiment of the present disclosure.

FIG. 13 is a pattern view schematically illustrating a configuration of a second front surface of a second circuit board according to the first embodiment of the present disclosure.

FIG. 14 is a pattern view schematically illustrating a configuration of a second-front-surface-side inner layer of the second circuit board according to the first embodiment of the present disclosure.

FIG. 15 is a pattern view schematically illustrating a configuration of a second-back-face-side inner layer of the second circuit board according to the first embodiment of the present disclosure.

FIG. 16 is a pattern view schematically illustrating a configuration of a second back face of the second circuit board according to the first embodiment of the present disclosure.

FIG. 17 is a pattern view schematically illustrating a configuration of a third back face of a third circuit board according to the first embodiment of the present disclosure.

FIG. 18 is a pattern view schematically illustrating a configuration of a fourth front surface of a fourth circuit board according to the first embodiment of the present disclosure.

FIG. 19 is a pattern view schematically illustrating a configuration of a fourth back face of the fourth circuit board according to the first embodiment of the present disclosure.

FIG. 20 is a pattern view schematically illustrating a configuration of the wiring board according to the first embodiment of the present disclosure.

FIG. 21 is a plan view schematically illustrating a configuration of a first insulating heat dissipation member according to the first embodiment of the present disclosure.

FIG. 22 is a plan view schematically illustrating a configuration of a second insulating heat dissipation member according to the first embodiment of the present disclosure.

FIG. 23 is a plan view schematically illustrating a configuration of a fourth insulating heat dissipation member according to the first embodiment of the present disclosure.

FIG. 24 is a plan view schematically illustrating a heat dissipation path of the power converter according to the first embodiment of the present disclosure.

FIG. 25 is a sectional view schematically illustrating the heat dissipation path of the power converter corresponding to FIG. 4.

FIG. 26 is a sectional view schematically illustrating the heat dissipation path of the power converter corresponding to FIG. 5.

FIG. 27 is an enlarged view of a region XXVII in FIG. 25.

FIG. 28 is a perspective view schematically illustrating a configuration of a power converter according to a second embodiment.

FIG. 29 is a flowchart illustrating a method for manufacturing the power converter of the second embodiment.

FIG. 30 is a perspective view illustrating the method for manufacturing the power converter of the second embodiment of the present disclosure.

FIG. 31 is a perspective view schematically illustrating a configuration of a cooler and a housing according to a third embodiment of the present disclosure.

FIG. 32 is a perspective view schematically illustrating a configuration of a power converter according to a fourth embodiment.

FIG. 33 is a sectional view schematically illustrating a configuration of a power converter according to a first modification of the fourth embodiment of the present disclosure.

FIG. 34 is a sectional view schematically illustrating a configuration of a power converter according to a second modification of the fourth embodiment of the present disclosure.

### DESCRIPTION OF EMBODIMENTS

Hereinafter, embodiments of the present disclosure will be described with reference to the drawings. In the following description, the same or corresponding parts are denoted by the same reference numerals, and overlapping description will not be repeated.

### First Embodiment

<Configuration of Power Converter 100>

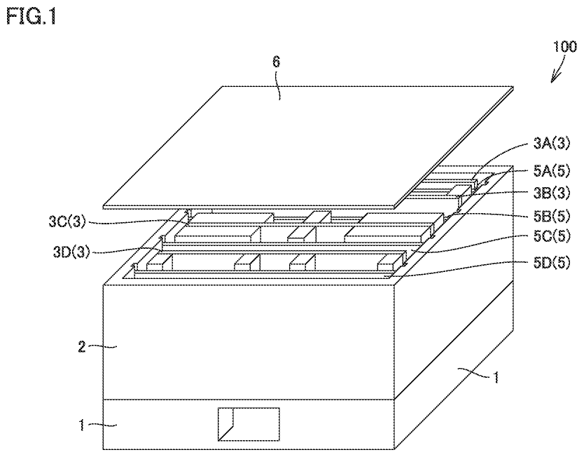

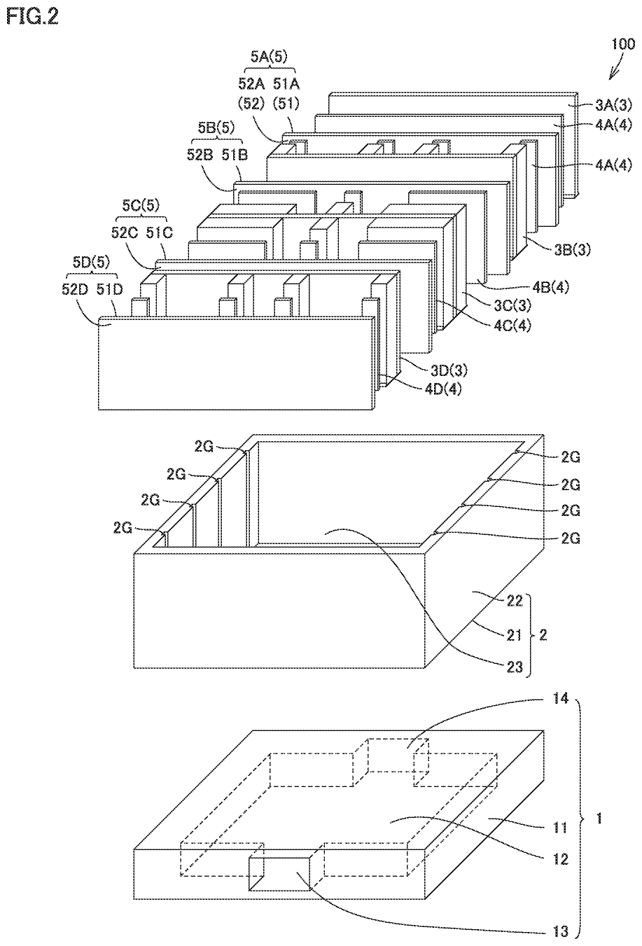

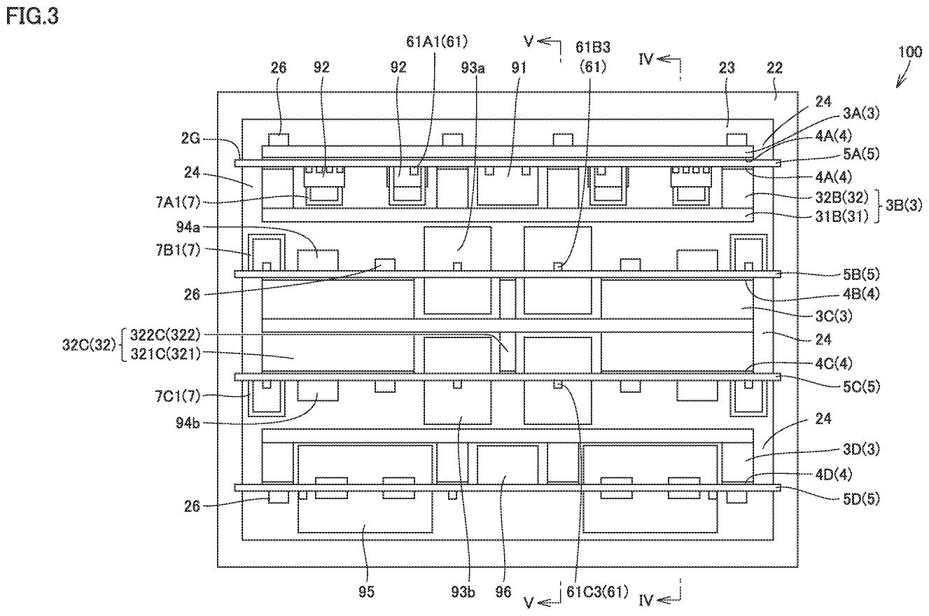

With reference to FIGS. 1 to 3, a configuration of a power converter 100 according to a first embodiment will be schematically illustrated. FIG. 1 is an exploded perspective view schematically illustrating the configuration of power converter 100 according to the first embodiment, and a wiring board 6 is separated from a housing 2 and a cooling plate 3 in FIG. 1. FIG. 2 is an exploded perspective view schematically illustrating the configuration of power converter 100 of the first embodiment, and wiring board 6 is not illustrated in FIG. 2. FIG. 3 is a plan view from above schematically illustrating the configuration of power converter 100 of the first embodiment, and wiring board 6 is not illustrated in FIG. 3.

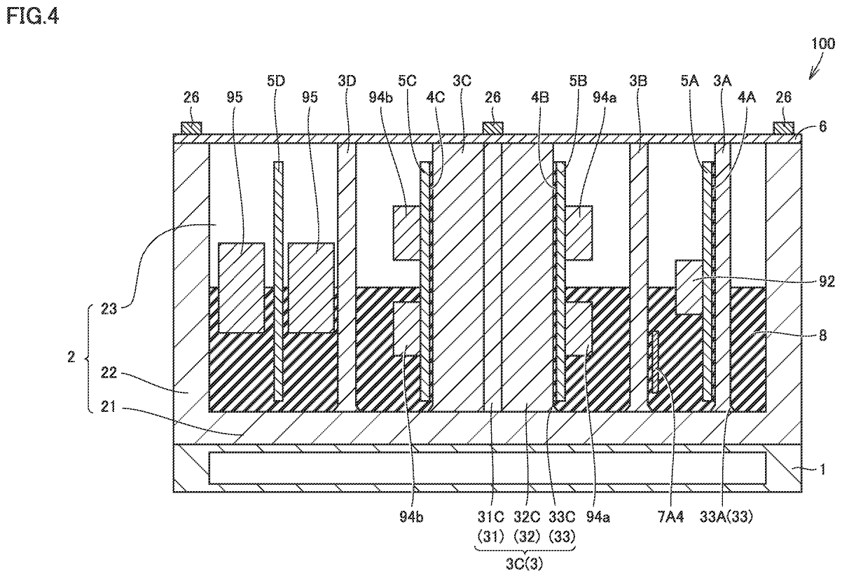

As illustrated in FIG. 2, power converter 100 includes a cooler 1, housing 2, at least one cooling plate 3, at least one insulating heat dissipation member 4, and at least one circuit board 5. As illustrated in FIG. 3, power converter 100 may include a heat generation component, wiring board 6 (see FIG. 1), a heat conduction member 7, and a filled insulating heat dissipation member 8 (see FIG. 4). Filled insulating heat dissipation member 8 is not illustrated in FIGS. 1 to 3.

For example, power converter 100 converts a loaded AC voltage into a DC voltage. For example, power converter 100 removes a high-frequency signal when converting the voltage.

<Configuration of Housing 2>

Illustrated with reference to FIG. 2, a configuration of housing 2 of the first embodiment is schematically illustrated. For example, housing 2 is formed by combining metal plates. For example, a material of housing 2 is generally aluminum (Al). The material of housing 2 is not limited to aluminum (Al) as long as the material has high thermal conductivity. For example, the material of housing 2 may be iron (Fe), copper (Cu), another alloy, or resin.

As illustrated in FIG. 2, housing 2 includes a bottom 21, a sidewall 22, and an internal space 23. Bottom 21 is connected to cooler 1. Sidewall 22 extends from bottom 21 on a side opposite to cooler 1 with respect to bottom 21. Internal space 23 is surrounded by bottom 21 and sidewall 22. As illustrated in FIG. 3, at least one cooling plate 3, at least one insulating heat dissipation member 4, and at least one circuit board 5 are accommodated in internal space 23 of housing 2.

For example, bottom 21 has a plate shape. The side on which cooler 1 is disposed with respect to bottom 21 is a lower side. The side on which sidewall 22 is disposed with respect to bottom 21 is an upper side. Cooler 1 is connected to a back face of bottom 21. Sidewall 22 is connected to a surface of bottom 21. Cooling plate 3 is connected to the surface of bottom 21.

Sidewall 22 extends upward with respect to bottom 21. Sidewall 22 may extend perpendicularly to bottom 21. Sidewall 22 surrounds internal space 23 together with bottom 21. Sidewall 22 may surround an entire circumference of internal space 23. Sidewall 22 may partially surround internal space 23.

A plurality of grooves 2G may be provided in sidewall 22. The plurality of grooves 2G are provided so as to face each of two sidewalls 22 facing each other. Circuit board 5 is inserted into the plurality of grooves 2G. The plurality of grooves 2G fix inserted circuit board 5. For example, four of the plurality of grooves 2G are provided in each of two sidewalls 22 facing each other, so that each of four circuit boards 5 is fixed to each of the plurality of grooves 2G. That is, at least one circuit board 5 can be fixed to the plurality of grooves 2G by being inserted into the plurality of grooves 2G.

Housing 2 may include an opening on the upper side. The opening is provided on the side opposite to bottom 21 with respect to sidewall 22. The opening is provided on the upper side of sidewall 22. Housing 2 may include the opening on a lateral side. When housing 2 includes the opening on the lateral side, sidewall 22 partially surrounds internal space 23.

<Configuration of Cooler 1>

With reference to FIGS. 1 and 2, a configuration of cooler 1 of the first embodiment is schematically illustrated below. As illustrated in FIG. 1, cooler 1 is connected to bottom 21. Specifically, cooler 1 is connected to the back face of bottom 21. Cooler 1 is mainly a water-cooled cooler 1. Cooler 1 may be an air-cooled cooler 1. As illustrated in FIG. 2, for example, cooler 1 includes a refrigerant (not illustrated), a cooling case 11, a flow path 12 provided in cooling case 11, and an opening provided in cooler 1. For example, the opening may include an inlet 13 and an outlet 14. The refrigerant flows into flow path 12 in cooling case 11 from inlet 13 and flows out of cooling case 11 from outlet 14. As a result, heat exchange is performed between cooler 1 and bottom 21. The heat generated from circuit board 5 and the heat generation component is dissipated by the heat exchange between cooler 1 and bottom 21. Thus, housing 2, cooling plate 3, insulating heat dissipation member 4, circuit board 5, and the heat generation component are cooled.

<Configuration of Cooling Plate 3>

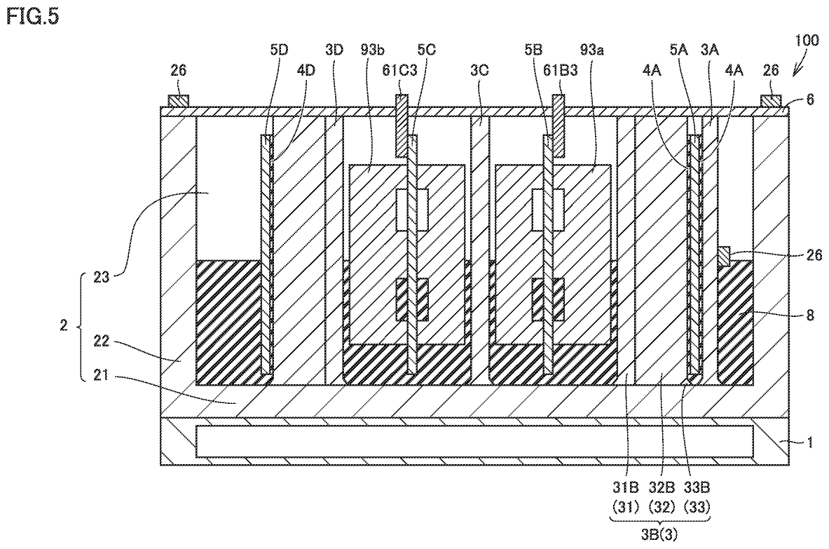

With reference to FIGS. 3 to 5, a configuration of cooling plate 3 of the first embodiment is schematically illustrated below. FIG. 4 is a sectional view taken along a line IV-IV of FIG. 3. FIG. 5 is a sectional view taken along a line V-V of FIG. 3.

A height direction of cooling plate 3 in the present disclosure is a direction perpendicular to bottom 21. A thickness direction of cooling plate 3 is a direction from the back face toward the front surface of cooling plate 3. The surface of the cooling plate is a surface of cooling plate 3 connected to circuit board 5. The back face of the cooling plate is a surface facing the front surface of the cooling plate. A width direction of cooling plate 3 is a direction perpendicular to each of the height direction and the width direction.

As illustrated in FIG. 3, at least one cooling plate 3 may include a plurality of cooling plates 3. Specifically, for example, at least one cooling plate 3 may include a first cooling plate 3A, a second cooling plate 3B, a third cooling plate 3C, and a fourth cooling plate 3D. Second cooling plate 3B may have the same shape as fourth cooling plate 3D. As illustrated in FIG. 3, first cooling plate 3A, second cooling plate 3B, third cooling plate 3C, and fourth cooling plate 3D may be disposed in parallel to each other in order of first cooling plate 3A, second cooling plate 3B, third cooling plate 3C, and fourth cooling plate 3D.

At least one cooling plate 3 may include one cooling plate (for example, second cooling plate 3B) and the other cooling plate (for example, fourth cooling plate 3D). One cooling plate 3B may have the same shape as other cooling plate 3D. Specifically, for example, second cooling plate 3B has the same shape as fourth cooling plate 3D.

As illustrated in FIG. 3, at least one cooling plate 3 is disposed with a gap 24 from sidewall 22. As illustrated in FIG. 4, at least one cooling plate 3 is connected to bottom 21 so as to stand upright with respect to bottom 21. Bottom 21 is sandwiched between cooling plate 3 and cooler 1. Cooling plate 3 is connected to cooler 1 through bottom 21. Cooling plate 3 is disposed above bottom 21. Cooling plate 3 may stand perpendicular to bottom 21.

As illustrated in FIG. 3, cooling plate 3 is disposed with gap 24 between cooling plate 3 and sidewall 22, so that cooling plate 3 does not contact sidewall 22. For example, desirably a dimension of gap 24 is greater than or equal to 1.0 mm. The dimension of gap 24 may be appropriately determined according to dimensional tolerance of cooling plate 3 and housing 2. The dimension in the width direction of cooling plate 3 is smaller than the dimension in the width direction of bottom 21. The dimension in the height direction of cooling plate 3 is smaller than the dimension in the height direction of sidewall 22.

For example, the material of cooling plate 3 is generally aluminum (Al). The material of cooling plate 3 is not limited to aluminum (Al) as long as the material has high thermal conductivity. For example, the material of cooling plate 3 may be iron (Fe), copper (Cu), another alloy, or resin.

As illustrated in FIG. 3, for example, cooling plate 3 has a plate shape or an uneven shape. Cooling plate 3 includes a plate 31. Specifically, the shape of plate 31 is a flat plate. Cooling plate 3 may include a plurality of protrusions 32. Protrusion 32 is attached to plate 31. Protrusion 32 is thicker than plate 31. Specifically, for example, the shape of protrusion 32 is a rectangular parallelepiped having a width smaller than that of plate 31. The heat generation component disposed on circuit board 5 may be accommodated between the plurality of protrusions 32 (recesses) attached to plate 31. An interval at which the plurality of protrusions 32 are disposed may be appropriately determined according to the dimension of the heat generation component.

As illustrated in FIG. 3, protrusion 32 may include a thick portion 321 and a thin portion 322. The dimension in the width direction of thick portion 321 is larger than that of thin portion 322. The dimension in the thickness direction of thick portion 321 is equal to that of thin portion 322. The dimensions of thick portion 321 and thin portion 322 may be appropriately determined according to the dimensions of the heat generation component and a calorific value.

As illustrated in FIGS. 4 and 5, cooling plate 3 may further include at least one hem 33. Hem 33 is connected to bottom 21. Hem 33 is attached to at least one of plate 31 and protrusion 32. Hem 33 may be attached to both surfaces of plate 31. Accordingly, bottom 21 is connected to at least one of plate 31 and protrusion 32 by hem 33. For example, hem 33 has a shape that gradually increases in the thickness direction from the upper side to the lower side in the height direction of cooling plate 3. The dimension of hem 33 may be appropriately determined as long as it does not interfere with other members.

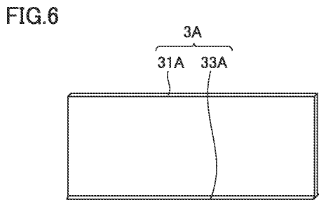

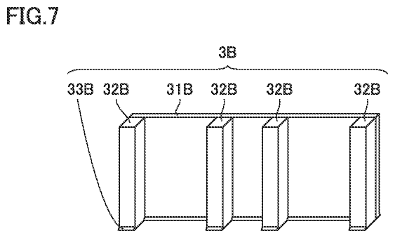

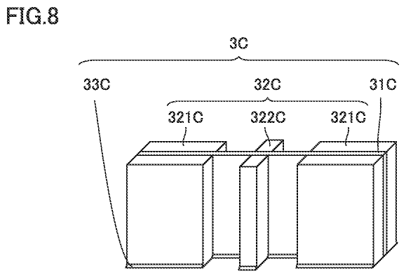

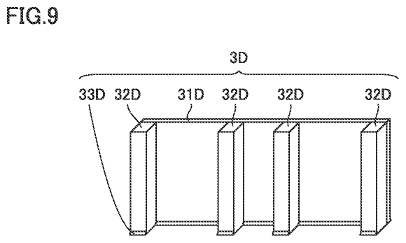

With reference to FIGS. 6 to 9, first cooling plate 3A, second cooling plate 3B, third cooling plate 3C, and fourth cooling plate 3D will be described in detail below. FIG. 6 is a perspective view schematically illustrating a configuration of first cooling plate 3A of the first embodiment. FIG. 7 is a perspective view schematically illustrating a configuration of second cooling plate 3B of the first embodiment. FIG. 8 is a perspective view schematically illustrating a configuration of third cooling plate 3C of the first embodiment. FIG. 9 is a perspective view schematically illustrating a configuration of fourth cooling plate 3D of the first embodiment.

As illustrated in FIG. 6, first cooling plate 3A specifically includes a first plate 31A and a plurality of first hems 33A. Specifically, first cooling plate 3A has a substantially plate shape. First hem 33A is attached to both surfaces of first plate 31A.

As illustrated in FIG. 7, second cooling plate 3B specifically includes a second plate 31B, a plurality of second protrusions 32B, and a plurality of second hems 33B. Second cooling plate 3B is thicker than first cooling plate 3A. Specifically, for example, the plurality of second protrusions 32B include four second protrusions 32B. Four second protrusions 32B have the same shape. Second hem 33B is attached to both surfaces of second plate 31B and second protrusion 32B.

As illustrated in FIG. 8, third cooling plate 3C specifically includes a third plate 31C, a plurality of third protrusions 32C, and a plurality of third hems 33C. Third hem 33C is attached to both surfaces of third plate 31C and third protrusion 32C. Each of the plurality of third protrusions 32C is attached to both sides of third plate 31C in mirror symmetry with respect to a center of third plate 31C. Each of the plurality of third protrusions 32C includes at least one third thick portion 321C and at least one third thin portion 322C. Specifically, for example, third protrusion 32C includes two third thick portions 321C and one third thin portion 322C. As illustrated in FIG. 3, third cooling plate 3C is thicker than first cooling plate 3A and second cooling plate 3B.

As illustrated in FIG. 9, fourth cooling plate 3D specifically includes fourth plate 31D, a plurality of fourth protrusions 32D, and a plurality of fourth hems 33D. Fourth cooling plate 3D has the same shape as second cooling plate 3B. Specifically, for example, the plurality of fourth protrusions 32D include four fourth protrusions 32D. Four fourth protrusions 32D have the same shape. Fourth hem 33D is attached to both surfaces of fourth plate 31D and fourth protrusion 32D. As illustrated in FIGS. 9 and 7, fourth cooling plate 3D has the same shape as second cooling plate 3B. As illustrated in FIG. 3, fourth cooling plate 3D is thicker than first cooling plate 3A and thinner than third cooling plate 3C.

<Configuration of Circuit Board 5>

With reference to FIGS. 2 and 3, a configuration of circuit board 5 of the first embodiment will be schematically illustrated below. As illustrated in FIG. 2, at least one circuit board 5 is connected to at least one cooling plate 3 with at least one insulating heat dissipation member 4 interposed therebetween. At least one circuit board 5 may include a plurality of circuit boards 5.

As illustrated in FIG. 3, for example, at least one circuit board 5 may specifically include a first circuit board 5A, a second circuit board 5B, a third circuit board 5C, and a fourth circuit board 5D. First circuit board 5A, second circuit board 5B, third circuit board 5C, and fourth circuit board 5D are disposed in the order of first circuit board 5A, second circuit board 5B, third circuit board 5C, and fourth circuit board 5D. Second circuit board 5B may have the same shape as third circuit board 5C.

For example, at least one circuit board 5 may include one circuit board (for example, second circuit board 5B) and the other circuit board (for example, third circuit board 5C). The one circuit board 5B may have the same shape as the other circuit board 5C. Specifically, for example, second circuit board 5B has the same shape as third circuit board 5C. The one circuit board 5B is disposed to face the other circuit board 5C.

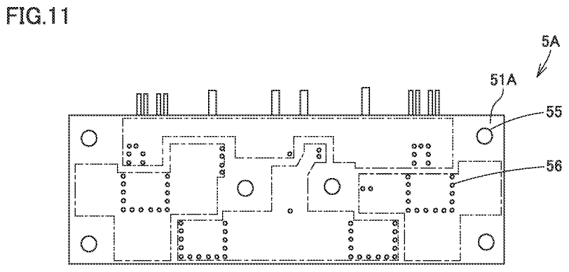

As illustrated in FIG. 3, circuit board 5 is fixed by being inserted into a plurality of grooves 2G provided in sidewall 22. For example, circuit board 5 is mechanically fixed to cooling plate 3 by screws 26 such that insulating heat dissipation member 4 is sandwiched between circuit board 5 and cooling plate 3. A plurality of screw holes 55 (see FIG. 11) through which screws 26 pass may be made in circuit board 5.

As illustrated in FIG. 2, circuit board 5 includes a front surface 51 and a back face 52 facing front surface 51. Front surface 51 and back face 52 may be electrically connected to each other through a plurality of through-holes 56 (see FIG. 11). A heat generation component is soldered to circuit board 5. Circuit board 5 is electrically connected to wiring board 6.

As illustrated in FIG. 2, first circuit board 5A includes a first front surface 51A and a first back face 52A facing first front surface 51A. Second circuit board 5B has a second front surface 51B and a second back face 52B facing second front surface 51B. Third circuit board 5C has a third front surface 51C and a third back face 52C facing third front surface 51C. Fourth circuit board 5D has a fourth front surface 51D and a fourth back face 52D facing fourth front surface 51D.

As illustrated in FIGS. 2 and 3, first cooling plate 3A is connected to first front surface 51A of first circuit board 5A. Second cooling plate 3B is connected to first back face 52A of first circuit board 5A, and faces second front surface 51B of second circuit board 5B. Third cooling plate 3C is connected to second back face 52B of second circuit board 5B and third front surface 51C of third circuit board 5C. Fourth cooling plate 3D is connected to fourth front surface 51D of fourth circuit board 5D, and faces third back face 52C of third circuit board 5C.

<Configuration of Wiring Board 6>

With reference to FIG. 1, a configuration of wiring board 6 of the first embodiment will be described below. Wiring board 6 functions as wiring of power converter 100.

As illustrated in FIG. 1, power converter 100 may further include wiring board 6 disposed on the opposite side of bottom 21 (see FIG. 2) with respect to sidewall 22 (see FIG. 2). Wiring board 6 is connected to at least one cooling plate 3, and electrically connected to at least one circuit board 5. For example, wiring board 6 is electrically connected to at least one circuit board 5 by soldering, welding, a conductive adhesive, or contact energization (press fit). The method for connecting wiring board 6 and at least one circuit board 5 is not limited to the above connection method as long as wiring board 6 and at least one circuit board 5 are electrically connected to each other.

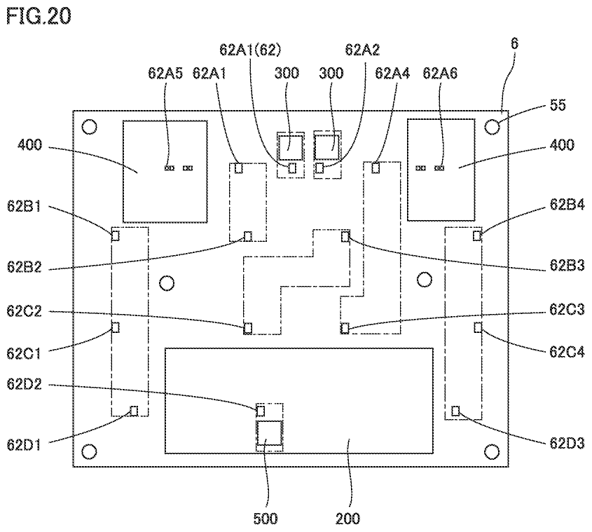

As illustrated in FIG. 1, wiring board 6 is disposed on the upper side of housing 2. Wiring board 6 covers the upper opening of housing 2. Wiring board 6 functions as a lid of housing 2. A plurality of screw holes 55 (see FIG. 20) may be made in wiring board 6. As illustrated in FIG. 4, specifically, for example, wiring board 6 is mechanically fixed to cooling plate 3 and housing 2 by screws 26.

<Configuration of Heat Generation Component>

With reference to FIG. 3, the heat generation component disposed on circuit board 5 will be described below. For example, the heat generation component is an electronic component. The heat generation component is electrically connected to circuit board 5. The heat generation component generates the heat by Joule heat when current flows through the heat generation component. The heat generation component is electrically insulated from cooling plate 3.

As illustrated in FIG. 3, for example, power converter 100 may specifically include an input capacitor 91, a switching element unit 92, a first transformer unit 93a, a second transformer unit 93b, a first rectifying element unit 94a, a second rectifying element unit 94b, a smoothing reactor 95, and an output capacitor 96 as the heat generation components.

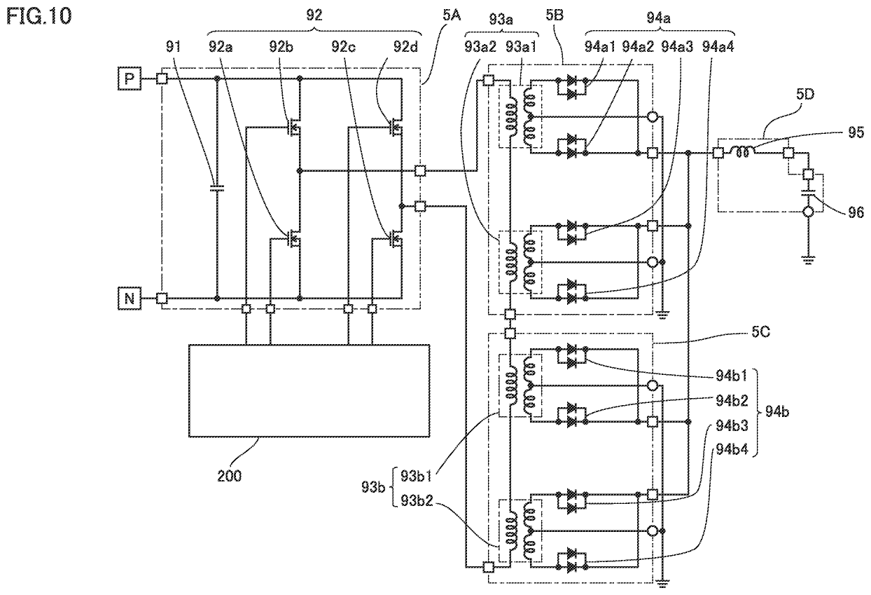

With reference to FIG. 10, configurations and functions of the heat generation component, circuit board 5, and wiring board 6 of the first embodiment will be schematically illustrated. FIG. 10 is a perspective view schematically illustrating the configuration of power converter 100 of the first embodiment. The functions of circuit board 5 and wiring board 6 of power converter 100 are classified into four types of a primary circuit, a transformer, a filter circuit, and wiring. First circuit board 5A functions as the primary circuit. Second circuit board 5B and third circuit board 5C together function as one transformer. Fourth circuit board 5D functions as the filter circuit. Wiring board 6 functions as the wiring.

As illustrated in FIG. 10, the AC voltage applied to input capacitor 91 disposed in the primary circuit (first circuit board 5A) is transformed and output by switching element unit 92 disposed in the primary circuit (first circuit board 5A), a control circuit 200 connected to the primary circuit (first circuit board 5A), and first transformer unit 93a and second transformer unit 93b that are disposed in the transformers (second circuit board 5B and third circuit board 5C). The voltage applied to the transformers (second circuit board 5B and third circuit board 5C) is converted into a stable DC voltage by first rectifying element unit 94a disposed at a subsequent stage of first transformer unit 93a, second rectifying element unit 94b disposed at a subsequent stage of second transformer unit 93b, and the filter circuit (fourth circuit board 5D) disposed at a subsequent stage of first rectifying element unit 94a and second rectifying element unit 94b.

Input capacitor 91 and switching element unit 92 are disposed in the primary circuit (first circuit board 5A). Input capacitor 91 stores a direct current. Input capacitor 91 is disposed in a front stage of switching element unit 92.

Switching element unit 92 is disposed at the subsequent stage of input capacitor 91. Switching element unit 92 includes at least one switching element. For example, switching element unit 92 includes four switching elements 92a to 92d. The switching element is made of silicon (Si) or silicon carbide (SiC). The structure of the switching element is generally an insulated gate bipolar transistor (IGBT), a metal oxide semiconductor field effect transistor (MOSFET), or the like. The material and structure of the switching element are not limited to the above materials and structures, but may be appropriately determined.

The transformer (second circuit board 5B and third circuit board 5C) is disposed at the subsequent stage of the primary circuit (first circuit board 5A). First transformer unit 93a and second transformer unit 93b, and a first rectifying element unit 94a and a second rectifying element unit 94b are disposed in the transformer (second circuit board 5B and third circuit board 5C). First transformer unit 93a and first rectifying element unit 94a are disposed on second circuit board 5B. Second transformer unit 93b and second rectifying element unit 94b are disposed on third circuit board 5C.

First transformer unit 93a includes at least one first transformer. For example, first transformer unit 93a includes two first transformers 93a1 and 93a2. Second transformer unit 93b includes at least one second transformer. For example, second transformer unit includes two second transformers 93b1 and 93b2. First rectifying element unit 94a includes at least one first rectifying element. For example, first rectifying element unit 94a includes four first rectifying elements 94a1 to 94a4. Second rectifying element unit 94b includes at least one second rectifying element. For example, second rectifying element unit includes four second rectifying elements 94b1 to 94b4.

First transformer unit 93a and second transformer unit 93b together function as one transformer. First transformer unit 93a and second transformer unit 93b convert the voltage output from the primary circuit (first circuit board 5A), and output the converted voltage. First transformer unit 93a and second transformer unit 93b are an insulating transformer.

First rectifying element unit 94a is disposed at the subsequent stage of first transformer unit 93a. Second rectifying element unit 94b is disposed at the subsequent stage of second transformer unit 93b. First rectifying element unit 94a and second rectifying element unit 94b rectify the AC voltages output from first transformer unit 93a and second transformer unit 93b into the DC voltages, respectively.

The filter circuit (fourth circuit board 5D) is disposed at the subsequent stage of the transformer (second circuit board 5B and third circuit board 5C). Smoothing reactor 95 and output capacitor 96 are disposed in the filter circuit (fourth circuit board 5D). The filter circuit (fourth circuit board 5D) functions as a low-pass filter. That is, the filter circuit (fourth circuit board 5D) removes a signal having a high frequency while allowing a signal having the direct current and a low frequency to pass.

A frequency fc of the signal removed by the filter circuit is as illustrated in the following equation by an inductance value L of smoothing reactor 95 and capacitance C of output capacitor 96.

fc=2π√(1/(LC))

<Configurations of First Circuit Board 5A to Fourth Circuit Board 5D and Wiring Board 6>

With reference to FIGS. 11 to 18, first circuit board 5A, second circuit board 5B, third circuit board 5C, fourth circuit board 5D, and the heat generation components disposed on first circuit board 5A, second circuit board 5B, third circuit board 5C, and fourth circuit board 5D will be described in detail below.

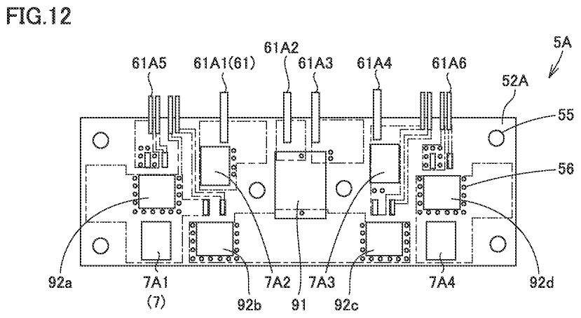

With reference to FIGS. 11 and 12, first circuit board 5A will be described. FIG. 11 is a pattern view illustrating first front surface 51A. FIG. 12 is a pattern view illustrating first back face 52A. Input capacitor 91 and switching element unit 92 (see FIG. 10) are disposed on first back face 52A.

As illustrated in FIG. 11, a plurality of through-holes 56 are made in first front surface 51A. Accordingly, first front surface 51A is electrically connected to first back face 52A. As illustrated in FIG. 12, input capacitor 91 and four switching elements 92a to 92d of switching element unit 92 are soldered to first back face 52A. Input capacitor 91 is disposed at the center of first back face 52A. Input capacitor 91 includes one terminal and the other terminal (not illustrated). One terminal of input capacitor 91 is connected to switching element 92b and switching element 92c through a circuit (not illustrated) provided on first back face 52A. The other terminal of input capacitor 91 is connected to switching element 92a and switching element 92d through a circuit (not illustrated) provided on first front surface 51A.

As illustrated in FIG. 12, switching element 92c is connected in series with switching element 92d through a circuit (not illustrated) provided on first front surface 51A. Switching element 92a is connected in series with switching element 92b through a circuit (not illustrated) provided on first back face 52A.

As illustrated in FIG. 12, first circuit board 5A is electrically connected to wiring board 6 by connection terminal 61A1 to 61A6 disposed on the upper side of first front surface 51A. Heat conduction members 7A1 to 7A4 may be disposed on first circuit board 5A.

With reference to FIGS. 10 and 13 to 16, second circuit board 5B will be described. Second circuit board 5B is a multilayer substrate. Specifically, for example, second circuit board 5B includes four layers. Second circuit board 5B includes second front surface 51B, a second-front-surface-side inner layer 53B, a second-back-face-side inner layer 54B, and second back face 52B. Second front surface 51B, second-front-surface-side inner layer 53B, second-back-face-side inner layer 54B, and second back face 52B are laminated in the order of second front surface 51B, second-front-surface-side inner layer 53B, second-back-face-side inner layer 54B, and second back face 52B, and electrically connected by the plurality of through-holes 56.

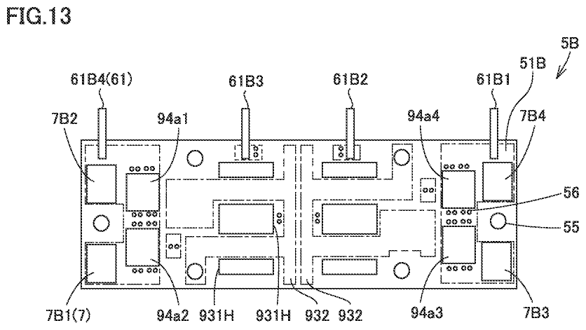

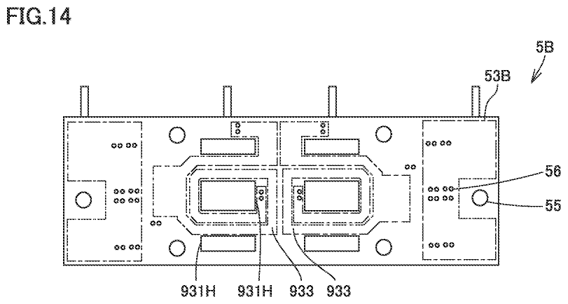

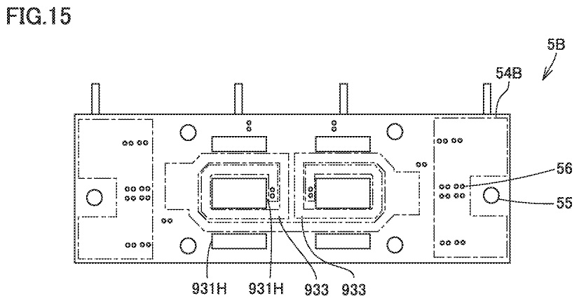

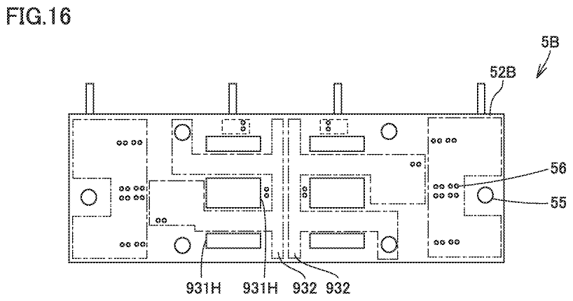

FIG. 13 is a pattern view illustrating second front surface 51B. FIG. 14 is a pattern view illustrating the second-front-surface-side inner layer 53B. FIG. 15 is a pattern view illustrating the second-back-face-side inner layer 54B. FIG. 16 is a pattern view illustrating second back face 52B. First rectifying element unit 94a (see FIG. 10) is disposed on second front surface 51B. First transformer unit 93a (see FIG. 10) is disposed on second circuit board 5B.

Each of first transformers 93a1 and 93a2 (see FIG. 10) of first transformer unit 93a includes a first transformer core (not illustrated), a first-transformer-side primary side winding 932 (see FIGS. 13 and 16), and a first-transformer-side secondary side winding 933 (see FIGS. 14 and 15). The first transformer core of the first transformer penetrates second circuit board 5B. As illustrated in FIGS. 13 to 16, a transformer core insertion hole 931H into which the first transformer core can be inserted may be made in second circuit board 5B.

As illustrated in FIG. 10, for example, two first transformers 93a1 and 93a2 are disposed on second circuit board 5B. Each of the first transformer cores (not illustrated) of first transformers 93a1 and 93a2 is disposed so as to pass through transformer core insertion hole 931H made in second circuit board 5B.

As illustrated in FIGS. 13 and 16, first-transformer-side primary side winding 932 is disposed at the center of each of second front surface 51B and second back face 52B. For example, the number of turns of first-transformer-side primary side winding 932 is eight turns.

As illustrated in FIGS. 14 and 15, first-transformer-side secondary side winding 933 is disposed at the center of each of second-front-surface-side inner layer 53B and second-back-face-side inner layer 54B. For example, the number of turns of the first-transformer-side secondary side winding 933 is one turn.

The number of turns of first-transformer-side primary side winding 932 and first-transformer-side secondary side winding 933 may be appropriately determined according to input and output. The shape-of the windings of first-transformer-side primary side winding 932 and first-transformer-side secondary side winding 933 are mainly a round wire, a rectangular wire, or the like. For example, when the number of turns of first-transformer-side primary side winding 932 and first-transformer-side secondary side winding 933 is greater than or equal to 0.5 turns and less than or equal to 2 turns, the substrate pattern of the multilayer substrate may be used as the winding.

By changing the ratio of the windings of first-transformer-side primary side winding 932 and first-transformer-side secondary side winding 933, the voltage on the primary side where first-transformer-side primary side winding 932 is disposed is transformed on the secondary side where first-transformer-side secondary side winding 933 is disposed.

As illustrated in FIG. 13, specifically, for example, four first rectifying elements 94a1 to 94a4 of first rectifying element unit 94a (see FIG. 10) are disposed on second front surface 51B of second circuit board 5B.

As illustrated in FIG. 13, second circuit board 5B is electrically connected to wiring board 6 by connection terminals 61B1 to 61B4 disposed on the upper side of second front surface 51B. Heat conduction member 7B1 to 7B4 may be disposed on second circuit board 5B.

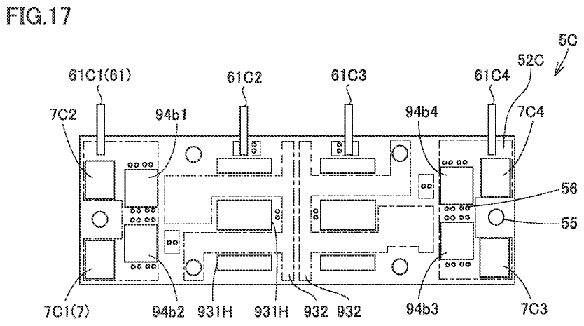

With reference to FIGS. 10 and 17, third circuit board 5C will be described. FIG. 17 is a pattern view illustrating third front surface 51C. Third circuit board 5C has the same shape and function as those of second circuit board 5B. Second rectifying element unit 94b (see FIG. 10) is disposed on third back face 52C. Second transformer unit 93b (see FIG. 10) is disposed on third circuit board 5C.

The second transformer of second transformer unit 93b includes a second transformer core (not illustrated), a second-transformer-side primary side winding 932 (see FIG. 17), and a second-transformer-side secondary side winding (not illustrated). The second transformer has the same configuration and function as the first transformer. The second transformer core, second-transformer-side primary side winding 932, and the second-transformer-side secondary side winding correspond to the first transformer core, first-transformer-side primary side winding 932, and the first-transformer-side secondary side winding, respectively. As illustrated in FIG. 17, transformer core insertion hole 931H into which the second transformer core can be inserted may be made in third circuit board 5C.

As illustrated in FIG. 17, specifically, for example, four second rectifying element 94b1 to 94b4 of second rectifying element unit 94b (see FIG. 10) are disposed on fourth back face 52D of fourth circuit board 5D. Second rectifying element unit 94b has the same configuration and function as those of first rectifying element unit 94a.

As illustrated in FIG. 17, third circuit board 5C is electrically connected to wiring board 6 by connection terminals 61C1 to 61C4 disposed on the upper side of third back face 52C. Heat conduction member 7C1 to 7C4 may be disposed on third circuit board 5C.

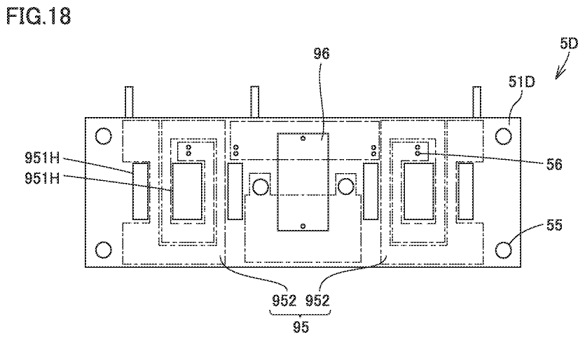

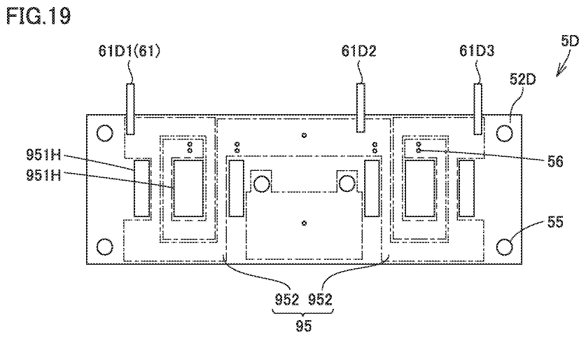

With reference to FIGS. 18 and 19, fourth circuit board 5D will be described. FIG. 18 is a pattern view illustrating fourth front surface 51D. FIG. 19 is a pattern view illustrating fourth back face 52D. As illustrated in FIG. 18, output capacitor 96 is disposed on fourth front surface 51D. Smoothing reactor 95 is disposed through fourth circuit board 5D. Fourth circuit board 5D may be connected to a reference potential (not illustrated) through screw 26 (see FIG. 3). Fourth circuit board 5D may be connected to a charge unit (not illustrated).

As illustrated in FIG. 18, output capacitor 96 is disposed at the center of fourth front surface 51D. Output capacitor 96 includes one terminal and the other terminal (not illustrated). One terminal of output capacitor 96 is connected to the reference potential through screw 26 (see FIG. 3). The other terminal of output capacitor 96 is connected to the charge unit and connection terminal 61.

Specifically, for example, smoothing reactor 95 includes two smoothing reactor cores (not illustrated) and four smoothing reactor patterns 952 (see FIGS. 18 and 19).

As illustrated in FIG. 18, a smoothing reactor insertion hole 951H into which smoothing reactor 95 can be inserted may be made in second circuit board 5B. The two smoothing reactor cores are disposed on the left and right sides of fourth circuit board 5D so as to penetrate fourth circuit board 5D. Two smoothing reactor patterns 952 are disposed on the left and right sides of fourth front surface 51D, respectively.

As illustrated in FIG. 19, two smoothing reactor patterns 952 are disposed on the left and right sides of fourth back face 52D. For example, the number of turns of smoothing reactor pattern 952 is two turns. For example, the number of turns of four smoothing reactor patterns 952 is eight turns in total. The number of turns of smoothing reactor pattern 952 may be appropriately determined.

As illustrated in FIG. 18, fourth circuit board 5D is electrically connected to wiring board 6 by connection terminals 61D1 to 61D3 disposed on the upper side of fourth back face 52D.

With reference to FIG. 20, wiring board 6 will be described below. FIG. 20 is a pattern view schematically illustrating a configuration of wiring board 6 of the first embodiment.

Wiring board 6 (see FIG. 1) is electrically connected to circuit board 5 (see FIG. 3). As illustrated in FIG. 20, an insertion hole 62 may be made in wiring board 6. Specifically, for example, insertion holes 62A1 to 62A6, 62B1 to 62B4, 62C1 to 62C4, and 62D1 to 62D3 may be made in wiring board 6. Insertion hole 62 is configured to allow insertion of connection terminal 61. Wiring board 6 is electrically connected to circuit board 5 by being soldered to connection terminal 61 of circuit board 5 inserted into insertion hole 62. The soldering method may be reflow soldering to entire wiring board 6 or soldering to a part of wiring board 6 by a solder jet.

Specifically, for example, connection terminals 61A1 to 61A6 (see FIG. 12) disposed on first circuit board 5A are inserted into insertion holes 62A1 to 62A6. Specifically, for example, connection terminals 61B1 to 61B4 (see FIG. 13) disposed on second circuit board 5B are inserted into insertion holes 62B1 to 62B4. Specifically, for example, connection terminals 61C1 to 61C4 (see FIG. 17) disposed on third circuit board 5C are inserted into insertion holes 62C1 to 62C4. Specifically, for example, connection terminals 61D1 to 61D3 (see FIG. 19) disposed on fourth circuit board 5D are inserted into insertion holes 62D1 to 62D3. Thus, wiring board 6 is electrically connected to first circuit board 5A, second circuit board 5B, third circuit board 5C, and fourth circuit board 5D.

<Configuration of Insulating Heat Dissipation Member 4>

With reference to FIGS. 2 and 3, insulating heat dissipation member 4 will be described below. As illustrated in FIG. 3, at least one insulating heat dissipation member 4 is disposed on at least one cooling plate 3. At least one insulating heat dissipation member 4 may include a plurality of insulating heat dissipation members 4. For example, at least one insulating heat dissipation member 4 may include one insulating heat dissipation member (for example, a first insulating heat dissipation member 4A) and the other insulating heat dissipation member (for example, a second insulating heat dissipation member 4B).

As illustrated in FIG. 2, insulating heat dissipation member 4 is sandwiched between cooling plate 3 and circuit board 5. Insulating heat dissipation member 4 is bonded to cooling plate 3 and circuit board 5. Insulating heat dissipation member 4 insulates cooling plate 3 from circuit board 5. For example, the material of insulating heat dissipation member 4 is an insulating heat dissipation sheet.

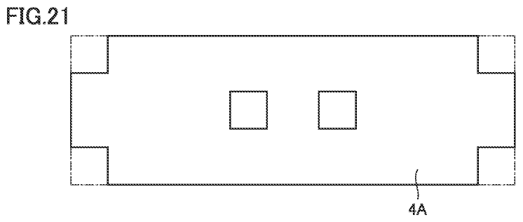

As illustrated in FIG. 3, the external dimension of insulating heat dissipation member 4 is less than or equal to the external dimensions of cooling plate 3 and circuit board 5 sandwiching insulating heat dissipation member 4. A peripheral region of screw hole 55 (see FIG. 11) of circuit board 5 does not need to be insulated. For this reason, insulating heat dissipation member 4 is hollowed out so as not to overlap the region (see FIG. 21).

As illustrated in FIG. 3, specifically, for example, at least one insulating heat dissipation member 4 includes first insulating heat dissipation member 4A, second insulating heat dissipation member 4B, a third insulating heat dissipation member 4C, and a fourth insulating heat dissipation member 4D. First insulating heat dissipation member 4A is disposed between first circuit board 5A and first cooling plate 3A and between first circuit board 5A and second cooling plate 3B. Second insulating heat dissipation member 4B is disposed between second circuit board 5B and third cooling plate 3C. Third insulating heat dissipation member 4C is disposed between third circuit board 5C and third cooling plate 3C. Fourth insulating heat dissipation member 4D is disposed between fourth circuit board 5D and fourth cooling plate 3D.

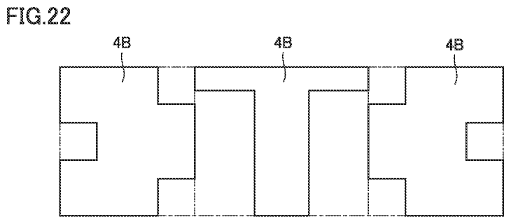

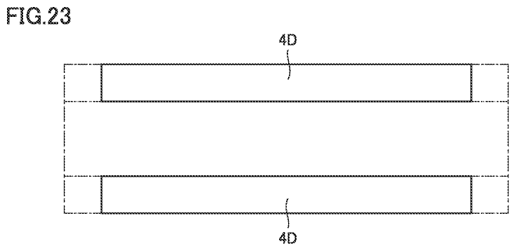

With reference to FIGS. 21 to 23, configurations of first insulating heat dissipation member 4A, second insulating heat dissipation member 4B, third insulating heat dissipation member 4C, and fourth insulating heat dissipation member 4D of the first embodiment are schematically illustrated below. FIG. 21 is a plan view schematically illustrating a configuration of first insulating heat dissipation member 4A of the first embodiment. FIG. 22 is a plan view schematically illustrating a configuration of second insulating heat dissipation member 4B of the first embodiment. FIG. 23 is a plan view schematically illustrating a configuration of fourth insulating heat dissipation member 4D of the first embodiment.

With reference to FIG. 21, first insulating heat dissipation member 4A will be described. The outer shape of first insulating heat dissipation member 4A and the outer shape of first circuit board 5A (see FIG. 11) are indicated by a solid line and an alternate long and short dash line, respectively.

With reference to FIG. 22, second insulating heat dissipation member 4B will be described. The outer shape of second insulating heat dissipation member 4B and the outer shape of second circuit board 5B (see FIG. 13) are indicated by a solid line and an alternate long and short dash line, respectively. The region around transformer core insertion hole 931H (see FIG. 13) made in second circuit board 5B does not need to be insulated. For this reason, second insulating heat dissipation member 4B is hollowed out so as not to overlap the region. Third insulating heat dissipation member 4C (see FIG. 3) has the same shape as second insulating heat dissipation member 4B.

With reference to FIG. 23, fourth insulating heat dissipation member 4D will be described. The outer shape of fourth insulating heat dissipation member 4D and the outer shape of fourth circuit board 5D (see FIG. 18) are indicated by a solid line and an alternate long and short dash line, respectively. The region around smoothing reactor insertion hole 951H (see FIG. 18) made in fourth circuit board 5D does not need to be insulated. For this reason, fourth insulating heat dissipation member 4D is hollowed out so as not to overlap the region.

<Other Configurations>

As illustrated in FIG. 20, power converter 100 may further include a control circuit 200, an input unit 300, a drive circuit 400, and an output unit 500. Control circuit 200, input unit 300, drive circuit 400, and output unit 500 may be attached to wiring board 6. Output unit 500 outputs the voltage converted by power converter 100. Drive circuit 400 is a circuit switching on and off switching element unit 92 (see FIG. 10) disposed on first circuit board 5A. Specifically, control circuit 200 includes a sensor and a microcomputer. The sensor obtains input and output information necessary for controlling power converter 100. When the microcomputer sends a control signal to drive circuit 400, power converter 100 obtains stable output by feedback control.

<Heat Dissipation Path>

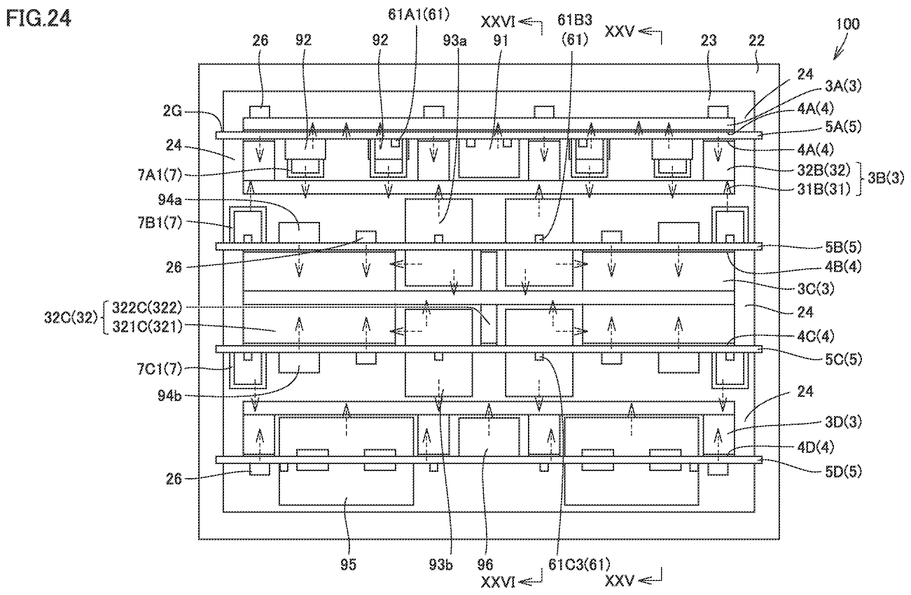

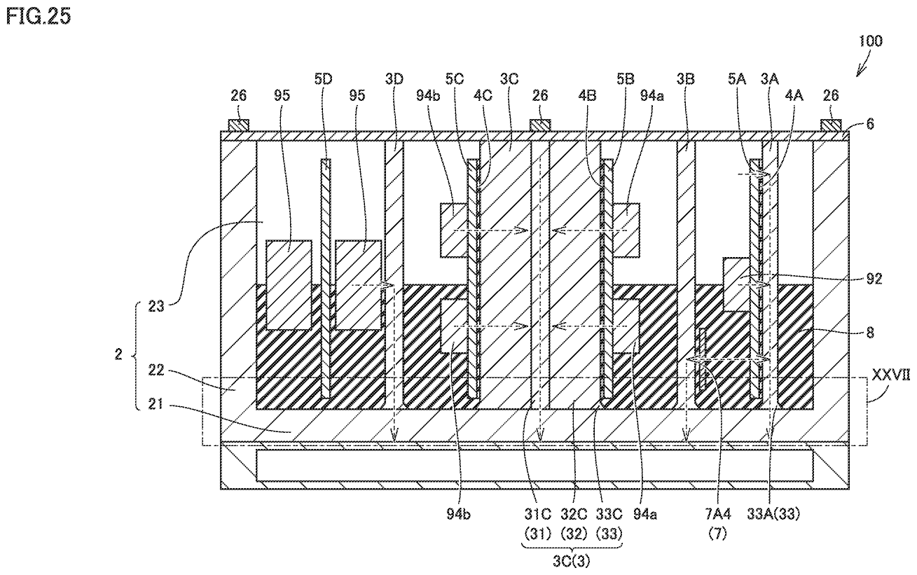

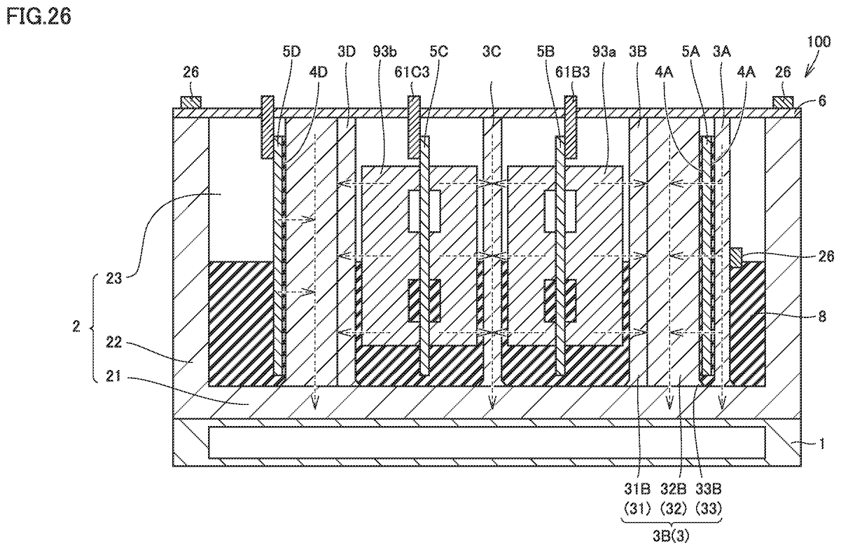

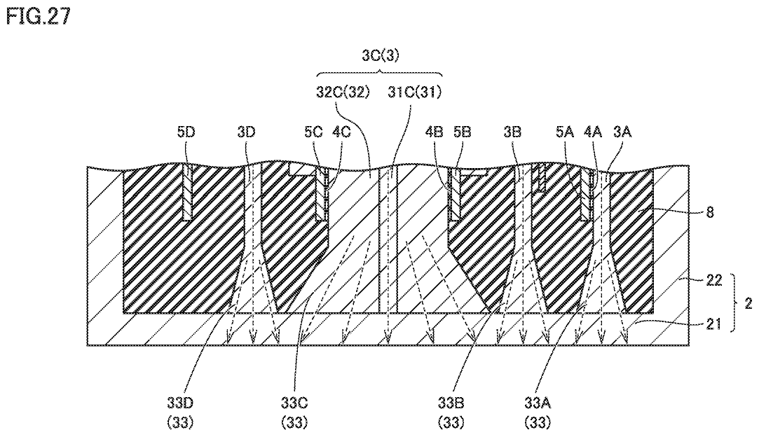

With reference to FIGS. 24 to 27, a heat dissipation path of power converter 100 of the first embodiment will be described below. The heat dissipation path is a path through which the heat generated from circuit board 5 and the heat generation component is transferred to cooler 1 and dissipated. The heat dissipation path is indicated by an arrow in FIGS. 24 to 27. FIG. 24 is a plan view schematically illustrating the heat dissipation path of power converter 100 of the first embodiment. FIG. 25 is a sectional view schematically illustrating the heat dissipation path of power converter 100 corresponding to FIG. 4. FIG. 26 is a sectional view schematically illustrating the heat dissipation path of power converter 100 corresponding to FIG. 5. FIG. 27 is an enlarged view of a region XXVII in FIG. 25.

Circuit board 5 and the heat generation component in FIG. 24 generate the heat by Joule heat when current flows therethrough. Specifically, for example, input capacitor 91, switching element unit 92, first transformer unit 93a, second transformer unit 93b, first rectifying element unit 94a, second rectifying element unit 94b, smoothing reactor 95, and output capacitor 96 generate the heat. The heat generated from circuit board 5 and the heat generation component is dissipated through the heat dissipation path.

As illustrated in FIG. 24, the heat generated from the heat generation component is transferred to cooling plate 3 through circuit board 5 and insulating heat dissipation member 4. The heat generated from circuit board 5 is transferred to cooling plate 3 through insulating heat dissipation member 4. As illustrated in FIGS. 25 and 26, the heat transferred to cooling plate 3 is dissipated by being transferred to cooler 1 through bottom 21. As illustrated in FIG. 27, the heat generated by the heat generation component and circuit board 5 may be transferred to cooler 1 through hem 33 of cooling plate 3.

As illustrated in FIG. 24, power converter 100 may further include heat conduction member 7 electrically connected to at least one circuit board 5. Heat conduction member 7 is disposed between at least one circuit board 5 and at least one cooling plate 3. The heat generated from circuit board 5 is dissipated through heat conduction member 7.

As illustrated in FIGS. 25 and 26, power converter 100 may further include filled insulating heat dissipation member 8 filled in internal space 23 of housing 2. The heat generated from the heat generation component and circuit board 5 is dissipated by being transferred to cooler 1 through filled insulating heat dissipation member 8.

As illustrated in FIGS. 25 and 26, the amount of filled insulating heat dissipation member 8 filled in internal space 23 may be appropriately adjusted according to the amount of the heat generated from circuit board 5 and the heat generation component and the amount of the heat passing through heat conduction member 7. Filled insulating heat dissipation member 8 may be partially filled so as to cover the heat generation component, or may be filled so as to fill entire internal space 23. For example, filled insulating heat dissipation member 8 may be filled only among bottom 21, circuit board 5, and cooling plate 3. For example, ½ of filled insulating heat dissipation member 8 may be filled from the bottom in the height direction of housing 2. For example, filled insulating heat dissipation member 8 may be filled so as to fill a gap between circuit board 5 accommodated in internal space 23 of housing 2 and cooling plate 3 without any gap. For example, the material of filled insulating heat dissipation member 8 is a potting material that cures in a gel state.

As illustrated in FIG. 24, the thickness of cooling plate 3 may be increased according to the calorific values of circuit board 5 and the heat generation component. Specifically, the thickness of cooling plate 3 may be increased by attaching protrusion 32 to plate 31. As illustrated in FIG. 27, the contact area between cooling plate 3 and bottom 21 may be increased according to the calorific values of circuit board 5 and the heat generation component. Specifically, the contact area between cooling plate 3 and bottom 21 may be increased by attaching hem 33 to plate 31 of cooling plate 3 and protrusion 32.

As illustrated in FIGS. 24 and 25, the heat generated from input capacitor 91 and switching element unit 92 disposed on first circuit board 5A is dissipated by being transferred to cooler 1 through first circuit board 5A, first insulating heat dissipation member 4A, first cooling plate 3A, and bottom 21. As illustrated in FIG. 26, the heat generated from switching element unit 92 disposed on first circuit board 5A is dissipated by being transferred to cooler 1 through first circuit board 5A, first insulating heat dissipation member 4A, second cooling plate 3B, and bottom 21.

As illustrated in FIGS. 24 and 25, the heat generated from first transformer unit 93a and first rectifying element unit 94a disposed on second circuit board 5B is dissipated by being transferred to cooler 1 through second circuit board 5B, second insulating heat dissipation member 4B, third cooling plate 3C, and bottom 21. As illustrated in FIG. 24, specifically, the heat generated from first transformer unit 93a may be dissipated through third protrusion 32C and third plate 31C. As illustrated in FIG. 26, the heat generated from the first transformer unit 93a may be dissipated through adjacent second cooling plate 3B.

As illustrated in FIGS. 24 and 25, the heat generated from second transformer unit 93b and second rectifying element unit 94b disposed on third circuit board 5C is dissipated by being transferred to cooler 1 through third circuit board 5C, third insulating heat dissipation member 4C, third cooling plate 3C, and bottom 21. As illustrated in FIG. 24, the heat generated from second transformer unit 93b may be specifically dissipated through third protrusion 32C and third plate 31C. As illustrated in FIG. 26, the heat generated from second transformer unit 93b may be dissipated through adjacent fourth cooling plate 3D.

As illustrated in FIGS. 24 and 25, the heat generated from output capacitor 96 disposed on fourth circuit board 5D and smoothing reactor 95 is dissipated by being transferred to cooler 1 through fourth circuit board 5D, fourth insulating heat dissipation member 4D, and fourth cooling plate 3D.

As illustrated in FIG. 24, the heat passing through heat conduction member 7 may be dissipated by being transferred to cooler 1 through adjacent cooling plate 3.

As illustrated in FIG. 24, when the calorific value of one circuit board (for example, third circuit board 5C) is greater than that of the other circuit board (for example, first circuit board 5A), one cooling plate (for example, third cooling plate 3C) connected to one circuit board 5C may be thicker than the other cooling plate (for example, first cooling plate 3A) connected to the other circuit board 5A. Specifically, for example, third cooling plate 3C is thicker than first cooling plate 3A. When the calorific value of one circuit board 5C is greater than that of the other circuit board 5A, one cooling plate 3C connected to one circuit board 5C may have a larger contact area with bottom 21 than the other cooling plate 3A connected to the other circuit board 5A. Specifically, for example, the contact area with bottom 21 of third cooling plate 3C is larger than that of first cooling plate 3A.

When the calorific value increases, the contact area between cooling plate 3 and bottom 21 may be increased in proportion to the increase in the calorific value. For example, when the calorific value increases by 1.3 times, the contact area may be increased by 1.3 times.

<Effects>

Effects of the first embodiment will be described below.

As illustrated in FIG. 3, the heat generation component is disposed on circuit board 5, and circuit board 5 is connected to cooling plate 3 with insulating heat dissipation member 4 interposed therebetween. As illustrated in FIGS. 4 and 5, cooling plate 3 is connected to bottom 21, and bottom 21 is connected to cooler 1. Accordingly, the heat generated from circuit board 5 and the heat generation component is transferred to cooler 1 through insulating heat dissipation member 4, cooling plate 3, and bottom 21. For this reason, the degradation of cooling performance of circuit board 5 is prevented regardless of the disposition of circuit board 5. Consequently, the cooling performance of circuit board 5 can be improved.

As illustrated in FIG. 3, cooling plate 3 is disposed with gap 24 between cooling plate 3 and sidewall 22 of housing 2, which facilitates the design as compared with the case where cooling plate 3 is in contact with sidewall 22. Consequently, power converter 100 that is easy to design can be provided.

When power converter 100 is designed such that cooling plate 3 and sidewall 22 come into contact with each other, an unintended gap may be generated between cooling plate 3 and sidewall 22 due to a dimensional tolerance of cooling plate 3 and sidewall 22. In this case, because the thermal resistance between cooling plate 3 and sidewall 22 increases, there is a possibility that the cooling performance expected in the design is not satisfied. Accordingly, power converter 100 is designed such that the cooling performance is satisfied even in the state where gap 24 is provided between cooling plate 3 and sidewall 22. Thus, power converter 100 satisfying the cooling performance is easy to design.

As illustrated in FIG. 24, because heat conduction member 7 is connected to circuit board 5, the heat generated from circuit board 5 is dissipated through heat conduction member 7. For this reason, the cooling performance of circuit board 5 can be improved.

As illustrated in FIG. 1, because wiring board 6 is connected to cooling plate 3, the heat generated from wiring board 6 can be transferred to cooler 1 through cooling plate 3. For this reason, the cooling performance of wiring board 6 can be improved.

As illustrated in FIGS. 25 and 26, because internal space 23 is filled with filled insulating heat dissipation member 8, the heat generated from circuit board 5 and the heat generation component can be transferred to cooler 1 through filled insulating heat dissipation member 8. Accordingly, the cooling performance can be improved.

Filled insulating heat dissipation member 8 is in contact with sidewall 22, so that the heat generated from circuit board 5 and the heat generation component can be transmitted to sidewall 22. Thus, the heat generated from circuit board 5 and the heat generation component can be transferred to cooler 1 through sidewall 22. Accordingly, the cooling performance can be improved. The heat dissipation path in this case is a path through which the heat generated from circuit board 5 and the heat generation component is transferred to cooler 1 through filled insulating heat dissipation member 8, sidewall 22, and bottom 21.

As illustrated in FIG. 25, when filled insulating heat dissipation member 8 is in contact with heat conduction member 7, the heat generated from circuit board 5 is dissipated through heat conduction member 7 and filled insulating heat dissipation member 8. Accordingly, the cooling performance of circuit board 5 can be improved.

As illustrated in FIG. 3, each of the plurality of circuit boards 5 sandwiches each of the plurality of insulating heat dissipation members 4, and is connected to the plurality of cooling plates 3. As illustrated in FIGS. 4 and 5, each of the plurality of cooling plates 3 is connected to bottom 21, so that each of the plurality of circuit boards 5 can be cooled. Accordingly, each of the plurality of circuit boards 5 can be cooled regardless of the position where each of the plurality of circuit boards 5 is disposed. For example, when the plurality of cooling plates 3 are connected to sidewall 22 so as to be stacked in the vertical direction and are not connected to bottom 21, the cooling performance of circuit board 5 relatively far from bottom 21 is degraded.

As illustrated in FIGS. 25 and 26, one cooling plate (for example, third cooling plate 3C) connected to one circuit board (for example, third circuit board 5C) having the large calorific value is thicker than the other cooling plate (for example, first cooling plate 3A) connected to the other circuit board (for example, first circuit board 5A) having the small calorific value. In this case, because the contact area between one cooling plate 3C and bottom 21 becomes larger, the thermal resistance between one cooling plate 3C and bottom 21 becomes smaller. Thus, one circuit board 5C having the large calorific value is cooled with higher cooling efficiency.

One cooling plate 3C has the larger contact area with bottom 21 than the other cooling plate 3A. In this case, the thermal resistance between one cooling plate 3C and bottom 21 is smaller than the thermal resistance between the other cooling plate 3A and bottom 21. Thus, one circuit board 5C having the large calorific value is cooled with higher cooling efficiency.

As illustrated in FIG. 27, when cooling plate 3 includes hem 33, the contact area between cooling plate 3 and bottom 21 increases. This increases the heat dissipation area, thereby improving the cooling performance.

As illustrated in FIGS. 7 and 9, when one cooling plate (for example, second cooling plate 3B) has the same shape as the other cooling plate (for example, fourth cooling plate 3D), the shapes of the plurality of cooling plates 3 can be made common. Thus, the manufacturing cost of power converter 100 can be reduced. Specifically, for example, second cooling plate 3B has the same shape as fourth cooling plate 3D, so that the cost for manufacturing second cooling plate 3B and fourth cooling plate 3D can be reduced.

As illustrated in FIGS. 13 and 17, when one circuit board (for example, second circuit board 5B) has the same shape as the other circuit board (for example, third circuit board 5C), the shapes of the plurality of circuit boards 5 can be made common. Thus, the manufacturing cost of power converter 100 can be reduced. Specifically, for example, second circuit board 5B has the same shape as third circuit board 5C, so that the cost for manufacturing second circuit board 5B and third circuit board 5C can be reduced.

As illustrated in FIG. 24, cooling plate 3 includes plate 31 and protrusion 32, so that the heat generation component can be disposed close to cooling plate 3. Specifically, the heat generation component is disposed so as to be sandwiched between two protrusions 32 (recesses), whereby the heat generation component can be efficiently cooled.

As illustrated in FIG. 24, when protrusion 32 includes thick portion 321 and thin portion 322, cooling plate 3 can be designed according to the dimensions and the calorific values of the plurality of heat generation components. Thus, the plurality of heat generation components can be efficiently cooled.

As illustrated in FIG. 24, the cooling performance is improved by increasing the heat dissipation path from the heat generation component to cooler 1. In addition, a region where the temperature is locally high in housing 2 can be reduced by increasing the heat dissipation path. Thus, the temperature in housing 2 can be made uniform, so that the thermal stress (temperature rise) of the heat generation component is reduced. Consequently, the life of the heat generation component can be extended. Specifically, for example, lives of switching element unit 92, first rectifying element unit 94a, and second rectifying element unit 94b can be extended by reducing the thermal stress of switching element unit 92, first rectifying element unit 94a, and second rectifying element unit 94b.

As illustrated in FIGS. 4 and 5, each of the plurality of cooling plates 3 is connected to bottom 21 so as to stand upright with respect to bottom 21, so that the plurality of cooling plates 3 can be disposed on bottom 21. Thus, power converter 100 can be downsized.

### Second Embodiment

A second embodiment has the same configuration, operation, and effect as those of the first embodiment described above unless otherwise specified. Consequently, the same components as those in the first embodiment are denoted by the same reference numerals, and the description thereof will not be repeated.

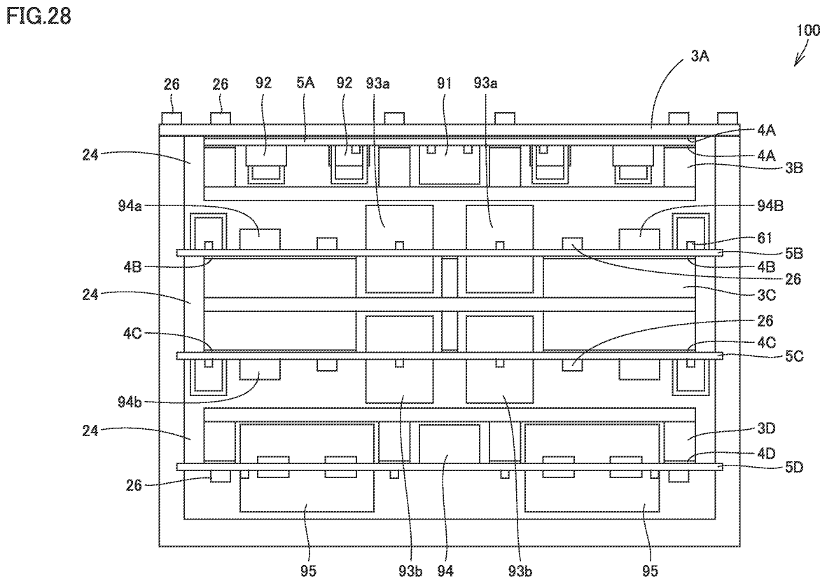

With reference to FIG. 28, a configuration of power converter 100 according to a second embodiment will be illustrated. FIG. 28 is a perspective view schematically illustrating the configuration of power converter 100 of the second embodiment.

As illustrated in FIG. 28, in the second embodiment, first cooling plate 3A is disposed so as to surround internal space 23 together with sidewall 22. First cooling plate 3A surrounds internal space 23 together with sidewall 22 by being disposed in the opening on the lateral side of housing 2. First front surface 51A is exposed to the outside of housing 2. First cooling plate 3A is detachably fixed to sidewall 22 by screws 26.

A manufacturing method of the second embodiment will be described below.

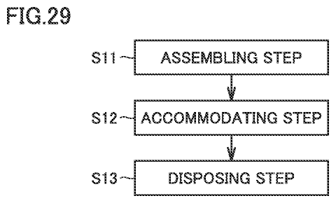

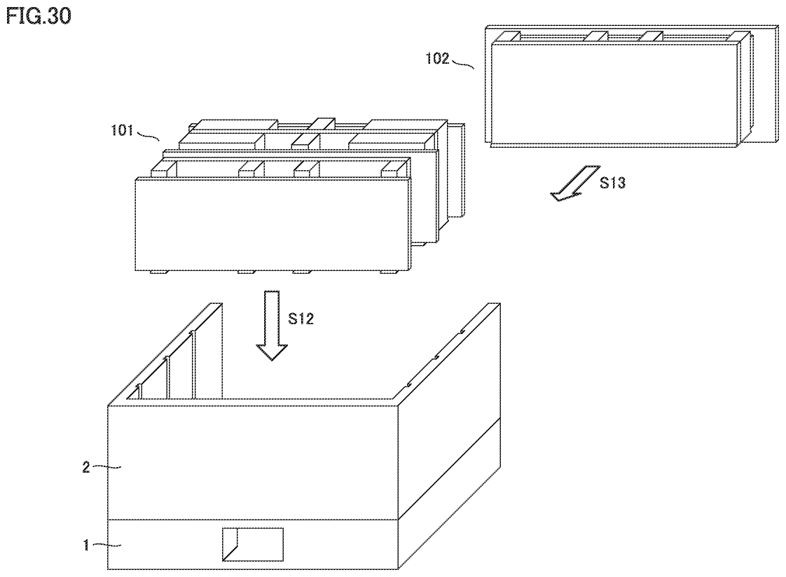

With reference to FIGS. 29 and 30, a method for manufacturing power converter 100 of the second embodiment will be schematically illustrated. FIG. 29 is a flowchart illustrating the method for manufacturing power converter 100 of the second embodiment. FIG. 30 is a perspective view illustrating the method of manufacturing power converter 100 of the second embodiment.

As illustrated in FIG. 29, the method for manufacturing power converter 100 of the second embodiment includes an assembling step S11, an accommodating step S12, and a disposing step S13. As illustrated in FIG. 30, in assembling step S11, a first subunit 101 is assembled by first circuit board 5A, first cooling plate 3A, and second cooling plate 3B. In assembling step S11, a second subunit 102 is assembled by second circuit board 5B, third circuit board 5C, fourth circuit board 5D, third cooling plate 3C, and fourth cooling plate 3D. In accommodating step S12, second subunit 102 is accommodated in internal space 23. In disposing step S13, first subunit 101 is disposed so as to surround internal space 23 together with sidewall 22 and bottom 21.

In accommodating step S12, the opening is provided on the lateral side of housing 2. In disposing step S13, second subunit 102 is disposed in the opening. Thus, the opening provided on the lateral side of housing 2 in accommodating step S12 is closed in disposing step S13.

<Effects>

After the plurality of cooling plates 3 and the plurality of circuit boards 5 are previously assembled as first subunit 101 and second subunit 102, first subunit 101 is accommodated in housing 2, and second subunit 102 is disposed so as to surround internal space 23 together with sidewall 22. That is, power converter 100 is manufactured after first subunit 101 and second subunit 102 are assembled. Thus, the manufacturing process is simplified as compared with the case where the plurality of cooling plates 3 and the plurality of circuit boards 5 are individually disposed in internal space 23.

Because the opening is provided on the side surface of housing 2 in accommodating step S12, first subunit 101 may be stored so as to pass through the opening on the upper side or stored so as to pass through the opening on the side surface when accommodated in internal space 23. Consequently, the manufacturing process of power converter 100 is simplified.

### Third Embodiment

A third embodiment has the same configuration, operation, and effect as those of the first embodiment described above unless otherwise specified. Consequently, the same components as those in the first embodiment are denoted by the same reference numerals, and the description thereof will not be repeated.

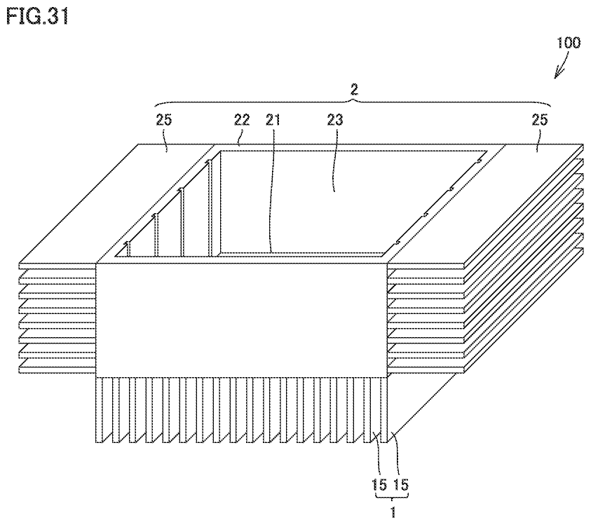

With reference to FIG. 31, a configuration of power converter 100 of the third embodiment will be schematically illustrated below. FIG. 31 is a perspective view schematically illustrating the configuration of power converter 100 of the third embodiment.

As illustrated in FIG. 31, housing 2 includes a plurality of side fins 25 disposed on the side opposite to internal space 23 with respect to sidewall 22. Cooler 1 includes a plurality of fins 15. In FIG. 31, side fins 25 are not disposed in a part of sidewall 22, but side fins 25 may be disposed over the entire circumference of sidewall 22. Power converter 100 of the third embodiment is different from power converter 100 of the first embodiment in that housing 2 includes the plurality of side fins 25 and that cooler 1 includes the plurality of fins 15.

Power converter 100 may be cooled by forcibly flowing the refrigerant to the plurality of fins 15 of cooler 1 and side fins 25 of housing 2. The refrigerant may be liquid or gas. When the refrigerant is liquid, cooler 1 is a water-cooled cooler 1. When the refrigerant is gas, cooler 1 is an air-cooled cooler 1.

The plurality of side fins 25 protrude to the outside of housing 2. The plurality of fins 15 protrude downward from bottom 21. For example, the shapes of side fin 25 and fin 15 are a plate shape. The materials of side fin 25 and fin 15 are typically made of aluminum (Al). The materials of side fin 25 and fin 15 is not limited to aluminum (Al) as long as the material has high thermal conductivity. For example, the materials of side fins 25 and fins 15 may be iron (Fe), copper (Cu), other alloys, or resin. The materials of side fin 25 and the plurality of fins may be the same as the material of housing 2.

<Effects>

Effects of the first embodiment will be described below.

Because housing 2 includes side fins 25, the heat dissipation area of housing 2 increases. For this reason, the cooling performance is further improved.

### Fourth Embodiment

A fourth embodiment has the same configuration, operation, and effect as those of the first embodiment described above unless otherwise specified. Consequently, the same components as those in the first embodiment are denoted by the same reference numerals, and the description thereof will not be repeated.

In power converter 100 of the first embodiment, the outer surface of the portion that is in contact with bottom 21 of at least one cooling plate 3 and the outer surface of the portion that is not in contact with bottom 21 of at least one cooling plate 3 are connected to each other by a linear structure (see FIG. 27). That is, hem 33 of cooling plate 3 has the shape linearly expanding toward bottom 21. The area of the portion of at least one cooling plate 3 that is in contact with bottom 21 is larger than the area of the portion of at least one cooling plate 3 that is not in contact with bottom 21. However, cooling plate 3 is not limited to the above shape as long as the area of the portion that is in contact with bottom 21 of cooling plate 3 is larger than the area of the portion that is not in contact with bottom 21 of cooling plate 3.

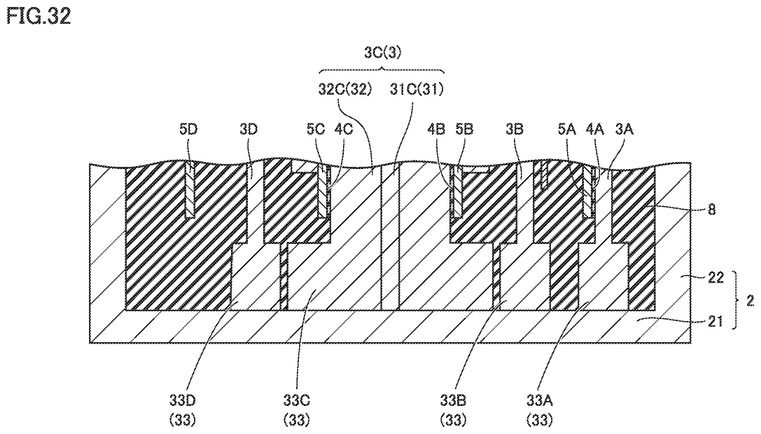

With reference to FIG. 32, a configuration of power converter 100 of the fourth embodiment will be illustrated. FIG. 32 is an enlarged sectional view schematically illustrating the configuration of power converter 100 of the fourth embodiment and corresponding to a XXVII region in FIG. 25.

As illustrated in FIG. 32, in power converter 100 of the fourth embodiment, the outer surface of the portion that is in contact with bottom 21 of at least one cooling plate 3 and the outer surface of the portion that is not in contact with bottom 21 of at least one cooling plate 3 are connected to each other by a step. That is, the outer surface of the portion that is in contact with bottom 21 of cooling plate 3 and the portion that is not in contact with bottom 21 of cooling plate 3 are connected to each other by a step at a right angle such as a staircase. Although not illustrated, the outer surface of the portion that is in contact with bottom 21 of cooling plate 3 and the outer surface of the portion not in contact with bottom 21 of cooling plate 3 may be connected to each other by a plurality of steps. That is, the number of steps may be at least two. Hem 33 has a plate shape. For this reason, hem 33 can be formed by a plate-shaped member.

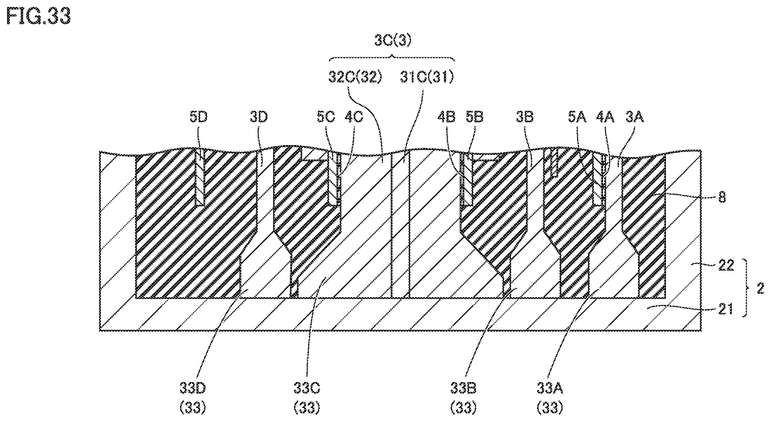

With reference to FIG. 33, a configuration of power converter 100 according to a first modification of the fourth embodiment will be schematically illustrated below. FIG. 33 is an enlarged sectional view schematically illustrating the configuration of power converter 100 according to the first modification of the fourth embodiment and corresponding to the XXVII region in FIG. 25.

As illustrated in FIG. 33, in power converter 100 of the first modification of the fourth embodiment, the outer surface of the portion that is in contact with bottom 21 of cooling plate 3 and the outer surface of the portion that is not in contact with bottom 21 of cooling plate 3 are obliquely connected to each other, and the portion that is in contact with bottom 21 of cooling plate 3 is in orthogonally contact with bottom 21. Thus, the amount of members used for cooling plate 3 can be reduced as compared with the case where hem 33 is formed by the plate-shaped member.

For example, the angle at which the heat spreads from the contact portion between the upper end of hem 33 and plate 31 toward the lower end of hem 33 is 45 degrees. The outer surface of the portion that is in contact with bottom 21 of cooling plate 3 may be inclined along the angle at which the heat spreads with respect to the outer surface of the portion that is not in contact with bottom 21 of cooling plate 3. For this reason, for example, the outer surface of the portion that is in contact with bottom 21 of cooling plate 3 is inclined by 45 degrees with respect to the outer surface of the portion that is not in contact with bottom 21 of cooling plate 3.

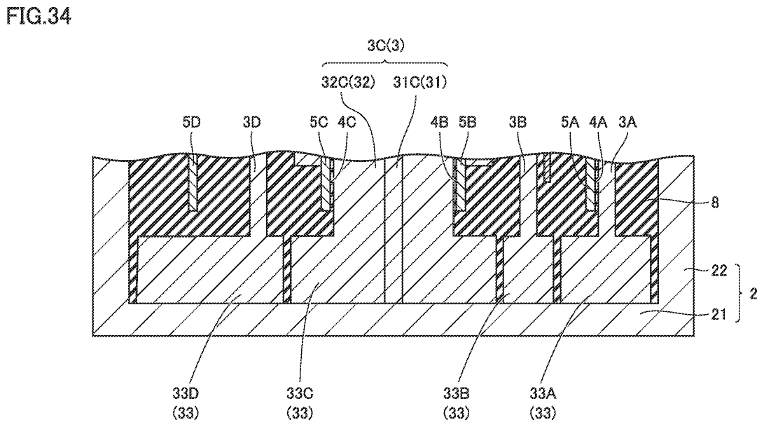

With reference to FIG. 34, a configuration of power converter 100 according to a second modification of the fourth embodiment will be schematically illustrated below. FIG. 34 is an enlarged sectional view schematically illustrating the configuration of power converter 100 according to the second modification of the fourth embodiment and corresponding to the XXVII region in FIG. 25.

As illustrated in FIG. 34, in power converter 100 of the second modification of the fourth embodiment, the plurality of hems 33 may be attached in a mirror-asymmetric manner with respect to the center of plate 31. For this reason, the thicknesses of the plurality of hems 33 can be easily changed as compared with the case where the plurality of hems 33 is attached in a mirror-symmetric manner with respect to the center of plate 31. Thus, the ratio of cooling plate 3 can be increased in the ratio of cooling plate 3 that is in contact with bottom 21 and filled insulating heat dissipation member 8 that is in contact with bottom 21. Accordingly, the heat radiation performance from cooling plate 3 to bottom 21 can be improved. In addition, because the ratio of filled insulating heat dissipation member 8 can be reduced, the cost of power converter 100 can be reduced when the cost of filled insulating heat dissipation member 8 is larger than the cost of cooling plate 3.

It should be considered that the disclosed embodiments are an example in all respects and not restrictive. The scope of the present disclosure is defined by not the description above, but the claims, and it is intended that all modifications within the meaning and scope of the claims and their equivalents are included in the present invention.

### REFERENCE SIGNS LIST

1: cooler
2: housing
3: cooling plate
3A: first cooling plate
3B: second cooling plate
3C: third cooling plate
4: insulating heat dissipation member
5: circuit board
5A: first circuit board
5B: second circuit board
5C: third circuit board
5D: fourth circuit board
6: wiring member
7: heat conduction member
8: filled insulating heat dissipation member
15: fin
21: bottom
22: sidewall
23: internal space
24: gap
25: side fin
51A: first front surface
51B: second front surface
51C: third front surface
51D: fourth front surface
52A: first back face
52B: Second back face
52C: third back face
52D: fourth back face
91: input capacitor
92: switching element unit
93a: first transformer unit
93b: second transformer unit
94a: first rectifying element unit
94b: second rectifying element unit
95: smoothing reactor
96: output capacitor

1. A power converter comprising:
a cooler;
a housing including a bottom connected to the cooler, a sidewall extending from the bottom on a side opposite to the cooler with respect to the bottom, and an internal space surrounded by the bottom and the sidewall;
at least one cooling plate connected to the bottom;
at least one insulating heat dissipation member disposed on the at least one cooling plate; and
at least one circuit board connected to the at least one cooling plate with the at least one insulating heat dissipation member interposed therebetween,
wherein the at least one cooling plate, the at least one insulating heat dissipation member, and the at least one circuit board are accommodated in the internal space of the housing, and
the at least one cooling plate is disposed with a gap from the sidewall.

2. The power converter according to claim 1, further comprising a heat conduction member electrically connected to the at least one circuit board,
wherein the heat conduction member is disposed between the at least one circuit board and the at least one cooling plate.

3. The power converter according to claim 1, further comprising a wiring board disposed on an opposite side of the bottom with respect to the sidewall,
wherein the wiring board is connected to the at least one cooling plate and is electrically connected to the at least one circuit board.

4. The power converter according to claim 1, wherein an area of a portion of the at least one cooling plate that is in contact with the bottom is larger than an area of a portion of the at least one cooling plate that is not in contact with the bottom.

5. The power converter according to claim 1, wherein an outer surface of the portion of the at least one cooling plate that is in contact with the bottom and an outer surface of the portion of the at least one cooling plate that is not in contact with the bottom are connected to each other by a linear structure.

6. The power converter according to claim 1, wherein an outer surface of the portion of the at least one cooling plate that is in contact with the bottom and an outer surface of the portion of the at least one cooling plate that is not in contact with the bottom are connected to each other by a step.

7. The power converter according to claim 1, further comprising a filled insulating heat dissipation member filled in the internal space.

8. The power converter according to claim 1, wherein the at least one cooling plate includes one cooling plate and an other cooling plate,
the at least one circuit board includes one circuit board and an other circuit board,
the at least one insulating heat dissipation member includes one insulating heat dissipation member and an other insulating heat dissipation member,
the one circuit board is connected to the one cooling plate with the one insulating heat dissipation member interposed therebetween, and
the other circuit board is connected to the other cooling plate with the other insulating heat dissipation member interposed therebetween.

9. The power converter according to claim 8, wherein the one circuit board has a larger calorific value than the other circuit board, and
the one cooling plate is thicker than the other cooling plate.

10. The power converter according to claim 9, wherein the one cooling plate has a larger contact area with the bottom than the other cooling plate.

11. The power converter according to claim 8, wherein a shape of the one cooling plate is identical to that of the other cooling plate.

12. The power converter according to claim 8, wherein a shape of the one circuit board is identical to that of the other circuit board.

13. The power converter according to claim 8, wherein the one circuit board is disposed to face the other circuit board.

14. The power converter according to claim 1, wherein a plurality of grooves are provided in the sidewall, and
the at least one circuit board can be fixed to the plurality of grooves by being inserted into the plurality of grooves.

15. The power converter according to claim 1, further comprising: an input capacitor; a switching element unit; a first transformer unit; a second transformer unit; a first rectifying element unit; a second rectifying element unit; a smoothing reactor; and an output capacitor,
wherein the at least one cooling plate includes a first cooling plate, a second cooling plate, a third cooling plate, and a fourth cooling plate,
the at least one circuit board includes a first circuit board, a second circuit board, a third circuit board, and a fourth circuit board,
the first circuit board, the second circuit board, the third circuit board, and the fourth circuit board are disposed in order of the first circuit board, the second circuit board, the third circuit board, and the fourth circuit board,
the first circuit board includes a first front surface and a first back face facing the first front surface, and the input capacitor and the switching element unit are disposed on the first back face,
the second circuit board includes a second front surface and a second back face facing the second front surface, and the first rectifying element unit is disposed on the second front surface,
the first transformer unit is disposed on the second circuit board,
the third circuit board includes a third front surface and a third back face facing the third front surface, and the second rectifying element unit is disposed on the third back face,
the second transformer unit is disposed on the third circuit board,
the fourth circuit board includes a fourth front surface and a fourth back face facing the fourth front surface, and the output capacitor is disposed on the fourth front surface,
the smoothing reactor is disposed on the fourth circuit board,
the first cooling plate is connected to the first front surface of the first circuit board,
the second cooling plate is connected to the first back face of the first circuit board and faces the second front surface of the second circuit board,
the third cooling plate is connected to the second back face of the second circuit board and the third front surface of the third circuit board,
the fourth cooling plate is connected to the fourth front surface of the fourth circuit board and faces the third back face of the third circuit board,
a shape of the second cooling plate is identical to that of the fourth cooling plate, and
a shape of the second circuit board is identical to that of the third circuit board.

16. The power converter according to claim 15, wherein the first cooling plate is disposed so as to surround the internal space together with the sidewall.

17. The power converter according to claim 1, wherein the housing includes a plurality of side fins disposed on a side opposite to the internal space with respect to the sidewall, and
the cooler includes a plurality of fins.

18. A method for manufacturing a power converter,
the power converter including:
a cooler;
a housing including a bottom connected to the cooler, a sidewall extending from the bottom on a side opposite to the cooler with respect to the bottom, and an internal space surrounded by the bottom and the sidewall;
at least one cooling plate connected to the bottom;
at least one insulating heat dissipation member disposed on the at least one cooling plate; and
at least one circuit board connected to the at least one cooling plate with the at least one insulating heat dissipation member interposed therebetween,
the at least one cooling plate, the at least one insulating heat dissipation member, and the at least one circuit board are accommodated in the internal space, and
the at least one cooling plate is disposed with a gap from the sidewall of the housing, wherein
the at least one cooling plate includes a first cooling plate, and a third cooling plate,
the at least one circuit board includes a first circuit board, and a second circuit board,
the method comprising:
assembling a first subunit by the first circuit board, and the first cooling plate, and assembling a second subunit by the second circuit board and the third cooling plate;
accommodating the second subunit in the internal space, and
disposing the first subunit such that the internal space is surrounded together with the sidewall and the bottom.
